(19) United States
(12) Patent Application Publication
(10) Pub. No.: US 2011/0291032 A1
(43) Pub. Date: Dec. 1, 2011

(54) ELECTROMAGNETIC SHIELDING COMPOSITION, ELECTROMAGNETIC SHIELDING DEVICE, ANTI-ELECTROSTATIC DEVICE AND METHOD OF MANUFACTURING ELECTROMAGNETIC SHIELDING STRUCTURE

(75) Inventors: Wen Hsien SUN, Taoyuan County (TW); Kao Der Chang, Taichung County (TW); Ming Jyh Chang, Keelung City (TW); Yu Ming Wang, Taichung City (TW); Chuen Shyong Chou, Hsinchu City (TW)

(73) Assignee: INDUSTRIAL TECHNOLOGY RESEARCH INSTITUTE, Hsinchu (TW)

(21) Appl. No.: 13/117,750

(22) Filed: May 27, 2011

(30) Foreign Application Priority Data
May 27, 2010 (TW) 099116931
Feb. 16, 2011 (TW) 100105049
May 18, 2011 (CN) 201110130025.X

(51) Int. Cl. G21F 1/00; B05D 5/12; H01B 1/22; H05K 1/09; H01F 1/01

(52) U.S. Cl. 250/515.1; 174/257; 252/62.54; 252/514; 427/77

(57) ABSTRACT

An electromagnetic shielding composition includes a carrier, a plurality of metal nanowires, and a plurality of nanoparticles. The plurality of metal nanowires are dispersed within the carrier and are in an amount of from 1 to 95 percent by weight of the electromagnetic shielding composition. The plurality of nanoparticles are dispersed within the carrier and are in an amount of from 0.5 to 60 percent by weight of the electromagnetic shielding composition.

### CROSS-REFERENCE TO RELATED APPLICATIONS

Not applicable.

### STATEMENT REGARDING FEDERALLY SPONSORED RESEARCH OR DEVELOPMENT

Not applicable.

### NAMES OF THE PARTIES TO A JOINT RESEARCH AGREEMENT

Not applicable.

### INCORPORATION-BY-REFERENCE OF MATERIALS SUBMITTED ON A COMPACT DISC

Not applicable.

### BACKGROUND OF THE INVENTION

1. Field of the Invention

The disclosure relates to an electromagnetic shielding composition, and particularly relates to an electromagnetic shielding composition including nanowires and nanoparticles.

2. Description of Related Art

Including Information Disclosed Under 37 CFR 1.97 and 37 CFR 1.98.

With the advancement of wireless technology, wireless communication devices such as mobile phones are widely used. Because wireless communication devices and base stations all may emit electromagnetic radiation, electromagnetic pollution fills our living environment. In addition, electronic products used in our daily life, such as computers or microwave ovens, may also emit weak electromagnetic energy.

According to a report released in 1998 by the World Health Organization, people who experience long-term exposure to electromagnetic radiation above safe levels are more likely to suffer from cardiovascular diseases, diabetes or cancer. Long-term exposure to high electromagnetic radiation level may cause disorders of reproductive, immune, or nervous systems, or cause miscarriage, deformed fetuses or sterility. Children exposed to electromagnetic radiation at high levels for a long period may suffer from abnormally slow bone growth, deterioration of hematopoietic function, and suffer from vision deterioration and retinal detachment. Thus, electromagnetic radiation seriously affects human health.

One conventional method to shield electromagnetic radiation is to use a metal piece or a metal shell. However, because metal is heavy, not easily formed into a desired shape, and is prone to oxidation during long-term use, metal is not suitable for use in many types of electronic devices.

Another method for shielding electromagnetic radiation is to form an electromagnetic shielding layer on a body using a mixture of metal particles and an adhesive or lacquer. The electromagnetic shielding layer is light-weight, and is not limited to the shape of a target. However, to obtain a desirable electromagnetic shielding effectiveness, high concentration of metal particles in the mixture is needed. Although a high concentration level of metal particles may enable better electromagnetic shielding effectiveness, the plasticity and the strength of the mixture may be lowered, and the advantages of the mixture such as ease of manufacturing, light weight, and low cost are lost. In addition, the electromagnetic shielding layer usually includes metal particles with a single shape. To improve the electromagnetic shielding performance by increasing the amount of metal particles with such a single shape does not significantly improve the electromagnetic shielding effectiveness.

In addition, conventional electromagnetic shielding layers need a thickness of 250 micrometers so as to have sufficient electromagnetic shielding effect. However, a thick electromagnetic shielding layer has poor uniformity and consumes more material.

In consideration of the deficiencies of conventional methods for shielding electromagnetic radiation, an electromagnetic shielding material having advantages such as high electromagnetic shielding effectiveness, low cost, and ease of use is required.

### BRIEF SUMMARY OF THE INVENTION

One embodiment of the present disclosure provides an electromagnetic shielding composition, which comprises a carrier, a plurality of metal nanowires, and a plurality of nanoparticles. The plurality of metal nanowires are dispersed within the carrier, wherein based upon the total weight of the composition taken as 100 percent, the metal nanowires are in an amount of between 1 and 95 percent by weight of the electromagnetic shielding composition. The plurality of nanoparticles are dispersed within the carrier, wherein based upon the total weight of the composition taken as 100 percent, the nanoparticles are in an amount of between 0.1 and 60 percent by weight of the electromagnetic shielding composition.

In another embodiment, an electromagnetic shielding composition is provided. The electromagnetic shielding composition comprises a carrier, a plurality of metal nanowires, and a plurality of nanoparticles. The plurality of metal nanowires are dispersed within the carrier. The plurality of metal nanowires have an aspect ratio of greater than 10. The metal nanowires comprise gold, silver, copper, indium, palladium, aluminum, iron, cobalt, nickel, an oxide thereof, or a mixture thereof, wherein the plurality of metal nanowires are in an amount of from 1 to 95 percent based upon the total weight of the electromagnetic shielding composition taken as 100 percent by weight. The plurality of nanoparticles are dispersed within the carrier. The nanoparticles have a size of less than 1000 nanometers. The nanoparticles comprise gold, silver, copper, indium, palladium, aluminum, iron, cobalt, nickel, an alloy thereof, an oxide thereof, or a mixture thereof, wherein the plurality of nanoparticles are in an amount of from 0.1 to 60 percent based upon the total weight of the electromagnetic shielding composition taken as 100 percent by weight.

In another embodiment, an electromagnetic shielding composition is provided. The electromagnetic shielding composition comprises a carrier, a plurality of metal nanowires, and a plurality of nanoparticles. The plurality of metal nanowires are dispersed within the carrier. The plurality of metal nanowires have an aspect ratio of greater than 10. The metal nanowires comprise gold, silver, copper, indium, palladium, aluminum, iron, cobalt, nickel, an oxide thereof, or a mixture thereof. The plurality of nanoparticles are dispersed within the carrier. The nanoparticles have a size of less than 1000 nanometers. The nanoparticles comprise gold, silver, copper, indium, palladium, aluminum, iron, cobalt, nickel, an alloy thereof, an oxide thereof, or a mixture thereof. The metal nanowires are in an amount of from 1 to 11 percent by weight, while the plurality of nanoparticles are in an amount of from 0.5 to 4 percent based upon the total weight of the electromagnetic shielding composition taken as 100 percent by weight such that the shielding effectiveness of the composition is greater than 10 dB.

In yet another embodiment, an electromagnetic shielding composition is provided. The electromagnetic shielding composition comprises a carrier, a plurality of metal nanowires, and a plurality of nanoparticles. The plurality of metal nanowires are dispersed within the carrier. The plurality of metal nanowires have an aspect ratio of from 20 to 500. The metal nanowires comprise gold, silver, copper, indium, palladium, aluminum, iron, cobalt, nickel, an oxide thereof, or a mixture thereof. The plurality of nanoparticles are dispersed within the carrier. The nanoparticles have a size of from 30 to 1000 nanometers. The nanoparticles comprise gold, silver, copper, indium, palladium, aluminum, iron, cobalt, nickel, an alloy thereof, an oxide thereof, or a mixture thereof, wherein the metal nanowires are in an amount of from 1 to 3 percent by weight, while the plurality of nanoparticles are in an amount of from 0.5 to 4 percent based upon the total weight of the electromagnetic shielding composition taken as 100 percent by weight such that the shielding effectiveness of the composition is greater than 10 dB.

One embodiment of the present disclosure discloses an electromagnetic shielding device, which includes a body member and a thin film. The thin film is formed on a surface of the body member for shielding electromagnetic radiation. The thin film comprises a plurality of metal nanowires dispersed within the thin film and being in an amount of between 1 and 95 percent by weight of the thin film and a plurality of nanoparticles dispersed within the thin film and being in an amount of between 0.1 and 60 percent by weight of the thin film.

One embodiment of the present disclosure further provides an anti-electrostatic device, which comprises a substrate and a thin film formed on the substrate. The thin film includes a plurality of metal nanowires dispersed within the thin film and being in an amount of between 1 and 95 percent by weight of the thin film taken as 100 percent and a plurality of nanoparticles dispersed within the thin film and being in an amount of between 0.1 and 60 percent by weight of the thin film taken as 100 percent.

The disclosure further provides a method of manufacturing an electromagnetic shielding structure. The method comprises the steps of: providing a target; providing a mixture comprising a plurality of metal nanowires having aspect ratios greater than 50; forming a first thin film on a surface of the target using the mixture; and heating the first thin film at a temperature in a range of from 50 to 250 degrees Celsius.

### BRIEF DESCRIPTION OF THE SEVERAL VIEWS OF THE DRAWINGS

The accompanying drawings, which are incorporated in and constitute a part of this specification, illustrate embodiments of the disclosure and, together with the description, serve to explain the principles of the invention.

FIGS. 1 and 2 are characteristic curve diagrams showing the relationship of the electromagnetic shielding effectiveness of samples with different contents of iron oxide nanoparticles and fixed nanowires content versus frequency according to one embodiment of the present disclosure;

FIG. 3 is a diagram showing the relationship between the electromagnetic shielding effectiveness of plural thin films and frequency according to one embodiment of the present disclosure, wherein the thin films include fixed content nanowires with an aspect ratio of 80 and different contents of iron oxide nanoparticles;

FIG. 4 is a diagram showing the relationship between the electromagnetic shielding effectiveness of thin films with different contents of iron oxide nanoparticles and fixed content nanowires (1.14 percent by weight) versus frequency according to one embodiment of the present disclosure;

FIGS. 5 and 6 are characteristic curve diagrams showing the relationship between the electromagnetic shielding effectiveness of thin films with increasing silver nanowires content versus frequency according to one embodiment of the present disclosure;

FIG. 7 is a characteristic curve diagram showing the relationship between the electromagnetic shielding effectiveness of thin films including silver nanowires and silver nanoparticles and frequency according to one embodiment of the present disclosure;

FIG. 8 is a simulated curve diagram showing the relationship between surface resistivity and nanowire concentration according to one embodiment of the present disclosure;

FIG. 9 is a simulated curve diagram showing the relationship between the electromagnetic shielding effectiveness of thin films including silver nanowires with an aspect ratio of 200 and surface resistivity according to one embodiment of the present disclosure;

FIG. 10 is a diagram showing the relationship of the electromagnetic shielding effectiveness of samples with different contents of nanowires (1.14, 3, and 10.45 wt %) versus frequency according to one embodiment of the present disclosure;

FIG. 11 is a curve diagram showing the relationship of volume percentage and the electromagnetic shielding effectiveness of samples with different aspect ratios according to one embodiment of the present disclosure;

FIG. 12 is a curve diagram showing the relationship between electromagnetic shielding effectiveness and frequency according to one embodiment of the disclosure;

FIG. 13 is a curve diagram showing the relationship between frequency and the electromagnetic shielding effectiveness of the film of the present disclosure and the films formed using commercial products according to one embodiment of the present invention;

FIG. 14 shows an electromagnetic shielding device according to one embodiment of the present invention;

FIG. 15 shows an anti-electrostatic device according to one embodiment of the present disclosure;

FIG. 16 shows an electromagnetic shielding structure according to one embodiment of the present invention;

FIG. 17 is a diagram showing a shielding effectiveness measurement, over a frequency range of from 1 to 1800 MHz, of a thin film formed by a mixture including 2.43 percent by weight silver nanowires and 1.45 percent by weight iron oxide particles according to one embodiment of the present invention;

FIG. 18 is a diagram showing a shielding effectiveness measurement, over a frequency range of from 1 to 18 GHz, of a thin film formed by a mixture including 2.43 percent by weight silver nanowires and 1.45 percent by weight iron oxide particles according to one embodiment of the present invention;

FIG. 19 is a diagram showing the relationship between the heating time and the shielding effectiveness of thin films formed by a mixture including 2.43 percent by weight silver nanowires and 1.45 percent by weight iron oxide particles according to one embodiment of the present invention;

FIG. 20 is a diagram showing the relationship between the heating time and the shielding effectiveness of thin films formed by a mixture including 2.43 percent by weight silver nanowires and 1.45 percent by weight iron oxide particles according to one embodiment of the present invention;

FIG. 21 is a diagram showing a shielding effectiveness measurement, over a frequency range of from 1 to 1800 MHz, of a thin film formed by a mixture including 3.49 percent by weight silver nanowires and 2.18 percent by weight iron oxide particles according to one embodiment of the present invention;

FIG. 22 is a diagram showing a shielding effectiveness measurement, over a frequency range of from 1 to 18 GHz, of a thin film formed by a mixture including 3.49 percent by weight silver nanowires and 2.18 percent by weight iron oxide particles according to one embodiment of the present invention;

FIG. 23 is a diagram showing shielding effectiveness measurements, over a frequency range of from 1 to 1800 MHz, of thin films formed by a mixture including 2.1 percent by weight silver nanowires and 0.55 percent by weight iron oxide particles and heated over different heating times and at different temperatures according to one embodiment of the present invention;

FIG. 24 is a diagram showing shielding effectiveness measurements, over a frequency range of from 100 to 1800 MHz, of a thin film formed by a mixture including 1.09 percent by weight silver nanowires and 3.69 percent by weight iron oxide particles and heated over different heating times according to one embodiment of the present invention;

FIG. 25 is a diagram representing the relationship between frequency and the strength of electromagnetic radiation measured from a hard disc without an electromagnetic shielding film;

FIG. 26 is a diagram representing the relationship between frequency and the strength of electromagnetic radiation measured from a hard disc coated with an electromagnetic shielding film;

FIG. 27 is a diagram representing the relationship between frequency and the strength of electromagnetic radiation measured in the horizontal direction from a video player without an electromagnetic shielding film;

FIG. 28 is a diagram representing the relationship between frequency and the strength of electromagnetic radiation measured in the horizontal direction from a video player coated with an electromagnetic shielding film;

FIG. 29 is a diagram representing the relationship between frequency and the strength of electromagnetic radiation measured in the vertical direction from a video player without an electromagnetic shielding film; and

FIG. 30 is a diagram representing the relationship between frequency and the strength of electromagnetic radiation measured in the vertical direction from a video player coated with an electromagnetic shielding film.

### DETAILED DESCRIPTION OF THE INVENTION

One embodiment of the disclosure provides an electromagnetic shielding composition comprising a carrier, a plurality of metal nanowires, and a plurality of nanoparticles. The plurality of metal nanowires are dispersed within the carrier. The plurality of nanoparticles are dispersed within the carrier. The plurality of metal nanowires and the plurality of nanoparticles are mixed with each other.

In one embodiment, the plurality of metal nanowires is in an amount of from 1 to 95 percent based on the total weight of the electromagnetic shielding composition taken as 100 percent by weight, and the plurality of nanoparticles are in an amount of between 0.1 and 60 percent based on the total weight of the electromagnetic shielding composition taken as 100 percent by weight. In another embodiment, the nanoparticles are in an amount of between 0.3 and 40 percent. In another embodiment, the nanoparticles are in an amount of between 0.5 and 20 percent. In another embodiment, the nanoparticles are in an amount of between 0.5 and 4 percent by weight. In another embodiment, the nanoparticles are in an amount of between 0.5 and 2 percent by weight.

In one embodiment, the plurality of metal nanowires are in an amount of between 1 and 95 percent based upon the total weight of the electromagnetic shielding composition taken as 100 percent by weight, and the plurality of nanoparticles are in an amount of between 0.5 and 60 percent based upon the total weight of the electromagnetic shielding composition taken as 100 percent by weight.

In one embodiment, the content ratio of the metal nanowires to the nanoparticles can be greater than 0.1.

One embodiment of the disclosure provides a solid body solidified from the above-mentioned composition. In one embodiment, the above-mentioned solid body can be a thin film of an electromagnetic shielding device or on an anti-electrostatic device. The metal nanowires can be formed as an electrically conductive structure so that the solid body can substantially conduct electricity.

In theory, the existence of nanoparticles can change optical path length difference; so electromagnetic energy may be dissipated within the interior of the solid body. Thus, mixing the nanoparticles with the metal nanowires can obviously improve the electromagnetic shielding effectiveness.

The sizes of the nanoparticles disclosed in the present invention can be less than 1000 nanometers.

In one embodiment, the nanoparticle can be an electrically conductive nanoparticle. In another embodiment, the nanoparticle can be a metal nanoparticle, the material of which can be gold, silver, copper, indium, palladium, aluminum, iron, cobalt, nickel, an alloy thereof, an oxide thereof, or mixture thereof, wherein the metal nanoparticles comprise between 0.5 and 2 percent based upon the total by weight of the electromagnetic shielding composition taken as 100 percent. In another embodiment, the nanoparticles may be gold-coated silver nanoparticles, silver-coated gold nanoparticles, gold-coated copper nanoparticles, copper-coated gold nanoparticles, silver-coated copper nanoparticles, copper-coated silver nanoparticles, or a combination thereof.

In one embodiment, the nanoparticle can be a magnetic nanoparticle, which can include magnetic iron. In another embodiment, the nanoparticle may be an insulated magnetic nanoparticle, which may include iron oxide or ferrous ferric oxide (Fe₃O₄), wherein the insulated magnetic nanoparticles can comprise between 0.5 and 4 percent or between 0.5 and 2 percent based upon the total weight of the electromagnetic shielding composition taken as 100 percent.

In one embodiment, the nanoparticles are electrically conductive particles, magnetic particles, insulated magnetic particles, or a mixture thereof.

In one embodiment, the nanoparticles can be nanoparticles of silver, iron oxide, or a mixture thereof, wherein the nanoparticles can comprise between 0.5 and 4 percent or between 0.5 and 2 percent based upon the total weight of the electromagnetic shielding composition taken as 100 percent.

In one embodiment, the diameters of the nanoparticles can be larger than 10 nanometers, or between 30 nanometers and 1000 nanometers. In one embodiment, the diameters of the nanoparticles can be in a range of from 30 nanometers to 500 nanometers.

As the above-mentioned composition is solidified as a solid body, the plurality of metal nanowires can be uniformly dispersed within the solid body. In one embodiment, the plurality of metal nanowires can be formed into a network structure in the solid body so as to make the solid body have low surface resistivity, for example, less than 10 ohms per square (Ω/sqr).

In another embodiment, the composition may include a small quantity of metal nanowires, and after the composition is solidified to a solid body, the metal nanowires are formed into a network or network-like structure, wherein the network or network-like structure renders the solid body to have high surface resistivity, for example, greater than 10 to 10⁶ ohms per square.

In another embodiment, the composition may include a small quantity of metal nanowires, and after the composition is solidified to a solid body, the metal nanowires are formed into a network or network-like structure, wherein the network or network-like structure renders the solid body to have high surface resistivity, for example, greater than 10⁴ to 10¹² ohms per square. As such, the solid body can be used for anti static electricity products.

The composition may include nanowires with high aspect ratios. Using the metal nanowires with high aspect ratios can significantly increase the level of the electromagnetic shielding effectiveness of the solid body. Further, using the metal nanowires with high aspect ratios can reduce the amount of use of the metal fillers.

In one embodiment, the metal nanowires can have aspect ratios of greater than 10, or, for example, between 20 and 500, or, for example, between 50 and 300.

In one embodiment, the material of the metal nanowire can be gold, silver, copper, indium, palladium, aluminum, iron, cobalt, nickel, an alloy thereof, an oxide thereof, or a mixture thereof. In another embodiment, the metal nanowires may be gold-coated silver metal nanowires, silver-coated gold metal nanowires, gold-coated copper metal nanowires, copper-coated gold metal nanowires, silver-coated copper metal nanowires, copper-coated silver metal nanowires, or a combination thereof.

The carrier can be a polymer, which includes thermoplastic resins such as acrylic resins or thermosetting resins such as epoxy resins. In one embodiment, the carrier can be a photo-cross-linking or a thermally cross-linking polymer.

Employing a mixture including metal nanoparticles or nanoparticles with high permeability constant to form a thin film on a target can cause the target to exhibit improved shielding effectiveness. If the thin film is treated with light energy or heat energy, the shielding effectiveness of the thin film can be further improved. Due to improved shielding effectiveness, the thickness of the thin film can be reduced while maintaining the same necessary level of shielding effectiveness. A thin film with a reduced thickness can be more uniform and consume less material. The thin film can be heated to a temperature in a range of from 50 to 250 degrees Celsius. The mixture can include nano-material and a carrier, wherein the carrier can include a polymer, and the nano-material can include metal nanowires, which can have aspect ratios of greater than 50. In one embodiment, the carrier can be a photo-cross-linking or a thermally cross-linking polymer.

The thin film can be heated to a temperature of from 50 to 250 degrees Celsius for a period of time (at least 5 minutes). As such, the shielding effectiveness of the thin film can be improved by at least 5 dB at frequencies of from 30 MHz and 16 GHz. In one embodiment, the thin film is heated to a temperature in a range of from 60 to 250 degrees Celsius for at least 5 minutes. In another embodiment, the heating time is above at least one hour. In one embodiment, the thin film is heated to a temperature of from 60 to 200 degrees Celsius for a period of from 5 minutes to 2 hours.

The metal nanowires may comprise gold, silver, copper, indium, palladium, aluminum, iron, cobalt, nickel, a mixture thereof, or an oxide thereof.

In one embodiment, the thin film can further comprise a plurality of nanoparticles, wherein the nanoparticles can be metal nanoparticles, nanoparticles with high permeability constant, or a mixture thereof. The metal nanoparticles can be silver nanoparticles. The nanoparticles with high permeability constant can be nanoparticles of iron oxide. The nanoparticles can have a size of less than 1000 nanometers (i.e., between 30 nanometers and 1000 nanometers or between 30 nanometers and 500 nanometers). The nanoparticles can comprise from 0.1 to 60 percent by weight, from 0.3 to 40 percent by weight, from 0.5 to 20 percent by weight, from 0.5 to 4 percent by weight, or from 0.5 to 2 percent by weight, based upon the total weight of the thin film taken as 100 percent by weight.

The target can have two thin films formed thereon and stacked on each other, wherein one thin film includes metal nanowires while another thin film includes metal nanoparticles or nanoparticles with high permeability constant.

The target depends on the application of the mixture. For example, when the mixture is used on electronic devices, the target may be the shell of the electronic devices, the printed circuit board of the electronic devices, or the components that need EMI protection in the electronic devices. In addition, the target can also be a substrate carrying a thin film.

Several examples are provided as follows for detailed explanation of the present disclosure.

### Experiment 1

The method described below can be used in formulating compositions including different types or contents of metal nanowires and nanoparticles. Initially, for each sample, silver nanowires are grown to have an aspect ratio of greater than 20 using a method such as the laser ablation method, the metal vapor synthesis method, the chemical reduction method, or the polyol method. The above-mentioned methods are well-known in the art; thus the detailed processes are not described here.

Subsequently, silver nanowires and nanoparticles are added into a polymer material to obtain a composition. The composition can be stirred using an ultrasonic vibrator and a planetary centrifugal mixer so as to disperse the silver nanowires and the nanoparticles within the polymer material. Thereafter, the composition is solidified to a solid body with a desirable shape. Finally, the electromagnetic shielding effectiveness of the solid body is tested. The electromagnetic shielding effectiveness test method can be a standard electromagnetic shielding effectiveness test method such as ASTM D4935-99. Usually, the shielding effectiveness (S.E.) can be obtained using the following equation:

$$S . E . = - 10 \times log \frac{{I}_{out}}{{I}_{in}}$$

where Iᵢₙ is the strength of electromagnetic radiation incident on a test sample, and Iₒᵤₜ is the strength of electromagnetic radiation through the test sample.

Table 1 below shows 6 compositions of different concentrations. Compositions (Samples 1 to 5) are prepared by adding the same weight percentage of silver nanowire (AgNW) and different weight percentages of iron oxide nanoparticles (Fe₃O₄NP) into a polymer material, wherein based on the total weight of the composition taken as 100 percent, the silver nanowires comprise 1.22 percent by weight of the composition, and the iron oxide nanoparticles comprise between 0 and 1.88 percent by weight of the composition. The polymer material can be ETERSOL 6515 unsaturated polyester manufactured by ETERNAL CHEMICAL Co., Ltd., Taiwan.

The polymer material includes polymethyl methacrylate solution. The polymethyl methacrylate can comprise from 45 to 55 percent by weight of the polymer material, and water can comprise from 45 to 55 percent by weight of the polymer material.

The aspect ratio of the silver nanowires can be 250, and the diameter of the iron oxide nanoparticle can be 100 nanometers. Sample 6 is prepared by mixing only iron oxide nanoparticles with the polymer material, wherein the concentration of the iron oxide nanoparticles is around 9.09 percent by weight. After Samples 1 to 6 are individually uniformly mixed, Samples 1 to 6 are used to separately form a thin film with a thickness of 50 micrometers. Finally, the electromagnetic shielding effectiveness of these thin films is tested.

TABLE 1

| | iron oxide nano- | | |
|---|---|---|---|
| | particles with | | |
| | a diameter of | silver nanowires with | |
| | 100 nanometers | an aspect ratio of 250 | ETERSOL 6515 |
| | (weight %) | (weight %) | (weight %) |
| Sample 1 | 0 | 1.22 | 49.39 |
| Sample 2 | 0.13 | 1.22 | 49.325 |
| Sample 3 | 0.31 | 1.22 | 49.235 |
| Sample 4 | 0.63 | 1.22 | 49.075 |
| Sample 5 | 1.88 | 1.22 | 48.45 |
| Sample 6 | 9.09 | 0 | 45.05 |

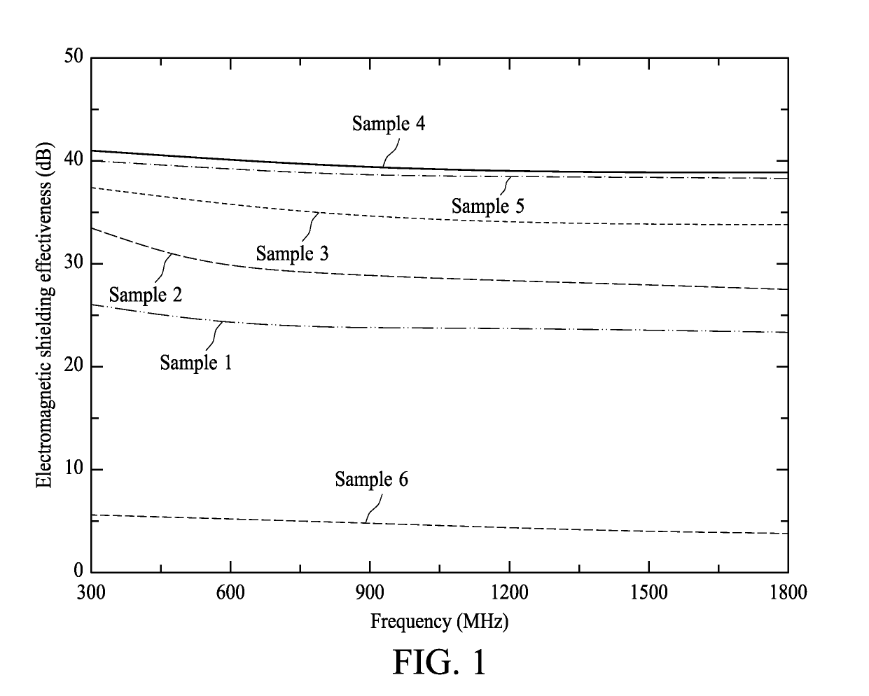

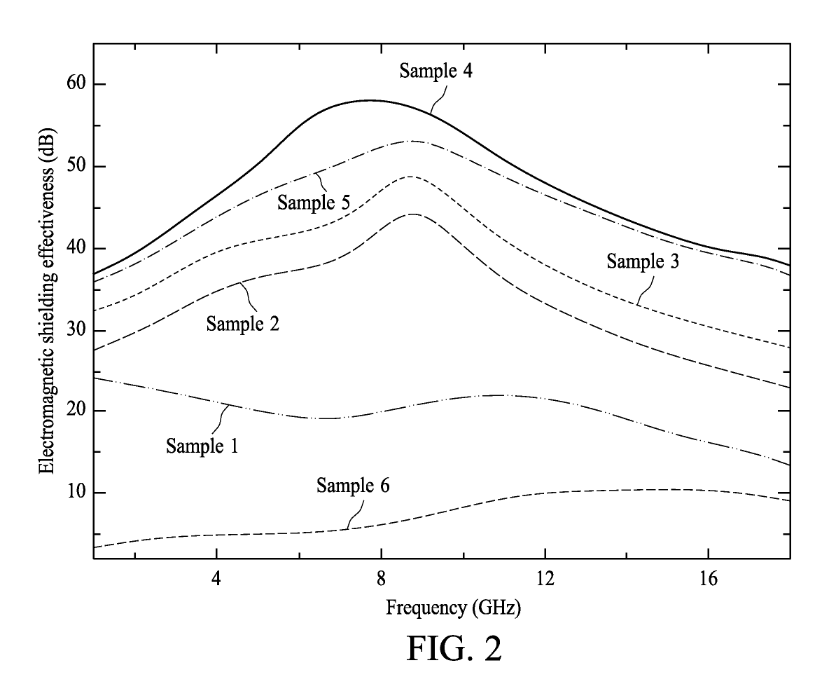

As shown in FIGS. 1 and 2, according to the electromagnetic shielding effectiveness test result for Samples 1 to 6, the electromagnetic shielding effectiveness is improved with the increase in the content of iron oxide nanoparticles. The electromagnetic shielding effectiveness of the thin films is effectively improved if the iron oxide nanoparticle content is in a range of from 0.1 to 3 percent by weight, and particularly improved if the iron oxide nanoparticle content is in a range of from 0.5 to 2 percent by weight.

From the above test results, it can be seen that the addition of a suitable amount of magnetically permeable dielectric nanoparticles to a thin film including metal nanowires can obviously improve the electromagnetic shielding effectiveness. However, if a high amount of permeable constant nanoparticles is added to a thin film including metal nanowires, the electromagnetic shielding effectiveness of the thin film decreases, contrary to the expectation, based on prior art knowledge, that the electromagnetic shielding effectiveness would be greater if more permeable constant nanoparticles are added. Therefore, when iron oxide nanoparticles have particle diameters of from 80 to 120 nanometers and silver nanowires have aspect ratios in a range of from 200 to 300, the amount of the iron oxide nanoparticles can be in a range of from 0.1 to 3 percent by weight, preferably in a range of from 0.5 to 2 percent by weight.

In addition, from the test result for Sample 6, it can be seen that although iron oxide nanoparticles are magnetically permeable dielectric nanoparticles, the thin film including 9.09 percent by weight of iron oxide nanoparticles has almost no electromagnetic shielding effect. The test result for Sample 6 teaches that the addition of iron oxide nanoparticles in an amount of less than 9.09 weight percent to a thin film including metal nanowires should not improve the electromagnetic shielding effectiveness of the thin film. However, from the results of the experiments of the disclosure, it can be found that the addition of a low amount of iron oxide nanoparticles to a thin film including metal nanowires can unexpectedly improve the electromagnetic shielding effectiveness of the thin film.

### Experiment 2

Table 2 below shows compositions (Samples 7 to 9) each including based on the total weight of the composition taken as 100 percent, silver nanowires in a concentration of 1.22 percent by weight and iron oxide nanoparticles in a specific amount ranging from 0 to 1.24 percent by weight, wherein the silver nanowire has an aspect ratio of 80, and the diameter of the iron oxide nanoparticle is around 100 nanometers. After mixing, Samples 7 to 9 are used to separately form a thin film with a thickness of 50 micrometers and the electromagnetic shielding effectiveness of these thin films is tested.

Each composition includes a polymer material that includes polymethyl methacrylate solution. Based on the total weight of the polymer material taken as 100 percent, Polymethyl methacrylate can comprise from 45 to 55 percent by weight of the polymer material, and water can comprise from 45 to 55 percent by weight of the polymer material.

TABLE 2

| | iron oxide nano- | | |
|---|---|---|---|
| | particles with | | |
| | a diameter of | silver nanowires with | polymethyl |
| | 100 nanometers | an aspect ratio of 80 | methacrylate |
| | (weight %) | (weight %) | (weight %) |
| Sample 7 | 0 | 1.22 | 49.39 |
| Sample 8 | 0.62 | 1.22 | 49.08 |
| Sample 9 | 1.24 | 1.22 | 48.67 |

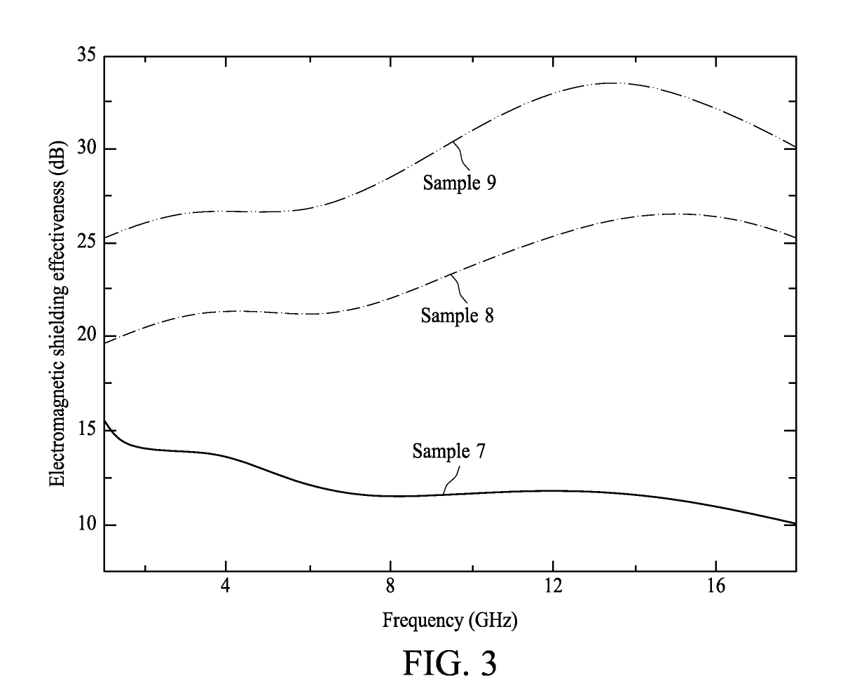

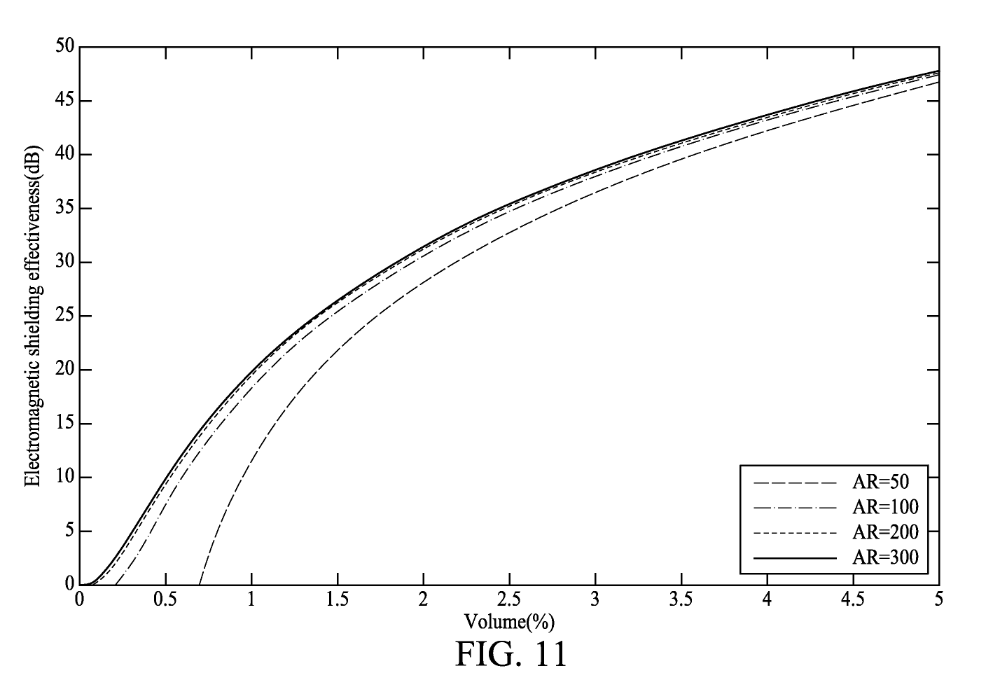

As shown in FIGS. 2 and 3, compared with the test results for Samples 1, 4, and 5, which include similar contents of iron oxide nanoparticles and silver nanowires, the thin films formed using Samples 7 to 9 have lower electromagnetic shielding effectiveness. Further, from the simulation result shown in FIG. 11, it can be inferred that the electromagnetic shielding effectiveness decreases with the decrease in the aspect ratio of the nanowires in use. Thus, the lower electromagnetic shielding effectiveness of the thin films formed using Samples 7 to 9 is likely a result of the use of nanowires with small aspect ratio.

For example, the thin film formed using Sample 4 exhibits electromagnetic shielding effectiveness of from 38 to 58 dB over a frequency range of from 2 to 16 GHz. In comparison, over the same frequency, the thin film formed using Sample 8 has electromagnetic shielding effectiveness in an acceptable range of from 20 to 27 dB.

In addition to the influence of the aspect ratio of a silver nanowire, similar to the results of the afore-mentioned experiments, thin films formed with Samples 7 to 9 having higher concentration of iron oxide nanoparticles exhibit higher electromagnetic shielding effectiveness.

Furthermore, the thin film formed using Sample 4 exhibits electromagnetic shielding effectiveness of from 38 to 58 dB over a frequency range of from 2 to 16 GHz. In comparison, as shown in FIG. 3, although the content of iron oxide nanoparticles is increased to 1.2 weight percent (Sample 9), the electromagnetic shielding effectiveness of the thin film is less than 35 dB. It can be seen that changing the aspect ratio of the nanowires in the thin film has a greater influence on the electromagnetic shielding effectiveness than changing the content of the nanoparticles in the thin film. Generally, the silver nanowires can have an aspect ratio of above 10, above 80, or between 100 and 300.

### Experiment 3

Table 3 below shows compositions (Samples 10 to 13), each of which includes 1.14 percent by weight of silver nanowires and iron oxide nanoparticles in a specific amount ranging from 0 to 1.99 percent by weight based on the total weight of the composition taken as 100 percent, wherein the silver nanowires have an aspect ratio of 250, and the diameters of the iron oxide nanoparticles are around 100 nanometers. After mixing, Samples 10 to 13 are used to separately form a thin film with a thickness of 50 micrometers for testing electromagnetic shielding effectiveness. The compositions include a polymer material that includes polymethyl methacrylate solution. Based on the total weight of the polymer material taken as 100 percent, Polymethyl methacrylate can comprise from 45 to 55 percent by weight of the polymer material, and water can comprise from 45 to 55 percent by weight of the polymer material.

TABLE 3

| | iron oxide nano- | | |
|---|---|---|---|
| | particles with | | |
| | a diameter of | silver nanowires with | polymethyl |
| | 100 nanometers | an aspect ratio of 250 | methacrylate |
| | (weight %) | (weight %) | (weight %) |
| Sample 10 | 0 | 1.14 | 49.43 |
| Sample 11 | 0.66 | 1.14 | 49.1 |
| Sample 12 | 1.33 | 1.14 | 48.765 |
| Sample 13 | 1.99 | 1.14 | 48.435 |

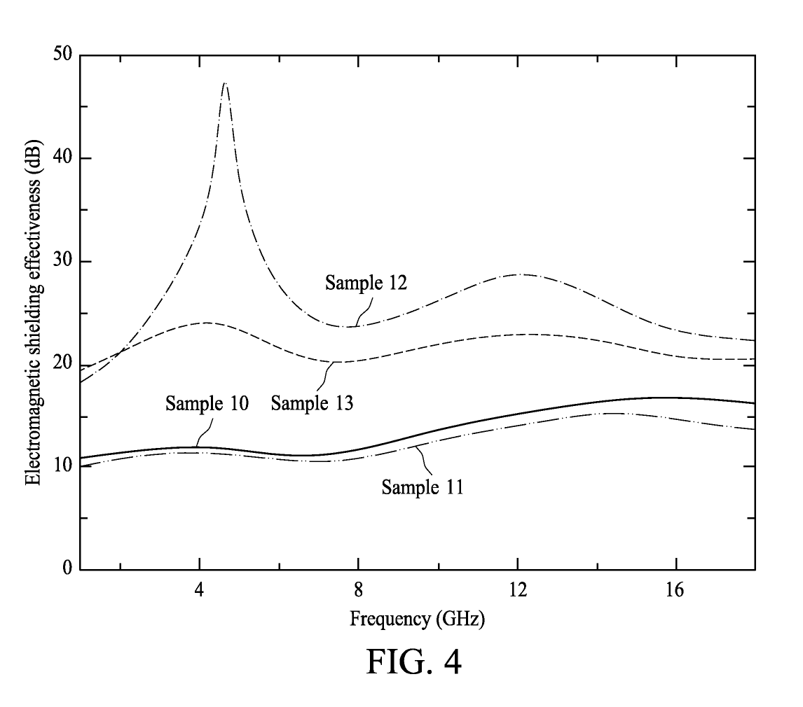

As shown in FIGS. 2 and 4, compared with the experiment results for the thin films having similar content of iron oxide nanoparticles in FIG. 2, the thin films formed using Samples 10 to 13 have lower electromagnetic shielding effectiveness due to their inclusion of low content of silver nanowires. For example, compared to the thin films formed using Samples 4 and 5, which have electromagnetic shielding effectiveness from 36 to 58 dB over a frequency range of from 7 to 16 GHz, over the same frequency range the thin film formed using Sample 12 has a lower electromagnetic shielding effectiveness of 22 to 27 dB.

From the results of Experiment 3, it can be seen that compared to the thin film without iron oxide nanoparticles, the thin film with 1.33 percent by weight of iron oxide nanoparticles can have significantly improved electromagnetic shielding effectiveness. Similarly, the addition of too many iron oxide nanoparticles, such as the 1.99 percent by weight of iron oxide nanoparticles in Sample 13, may have adverse impact on the electromagnetic shielding effectiveness.

As a result, according to the results from Samples 4 and 5 and Samples 11, 12 and 13, the electromagnetic shielding effectiveness of a thin film including nanowires in an amount of less than 3 percent by weight cannot be improved by adding nanoparticles in an amount of more than 2 percent by weight. Therefore, when iron oxide nanoparticles are between 80 to 120 nanometers in diameter, silver nanowires have aspect ratios of from 200 to 300, and the thin film includes nanowires of from 1.0 to 1.3 percent by weight, the concentration of the iron oxide nanoparticles is preferably in a range of from 0.1 to 3 percent by weight, more preferably in a range of from 0.2 to 2 percent by weight, and most preferably in a range of from 1 to 2 percent by weight.

### Experiment 4

Table 4 below shows compositions (Samples 14 to 17) each including 3 percent by weight silver nanowires and iron oxide nanoparticles in a specific amount in a range of from 0 to 1.79 percent by weight based on the total weight of the composition taken as 100 percent, wherein the silver nanowires have an aspect ratio of 250, and the diameters of the iron oxide nanoparticles are around 0.5 micrometers. After mixing, Samples 14 to 17 are used to separately form a thin film with a thickness of 50 micrometers for testing electromagnetic shielding effectiveness. The compositions include a polymer material that includes polymethyl methacrylate solution. Based on the total weight of the polymer material taken as 100 percent, Polymethyl methacrylate can comprise from 45 to 55 percent by weight of the polymer material, and water can comprise from 45 to 55 percent by weight of the polymer material.

TABLE 4

| | iron oxide nano- | | |
|---|---|---|---|
| | particles with | | |
| | a diameter of | silver nanowires with | polymethyl |
| | 0.5 micrometers | an aspect ratio of 250 | methacrylate |
| | (weight %) | (weight %) | (weight %) |
| Sample 14 | 0 | 3 | 48.5 |
| Sample 15 | 0.61 | 3 | 48.195 |
| Sample 16 | 1.2 | 3 | 47.9 |
| Sample 17 | 1.79 | 3 | 47.605 |

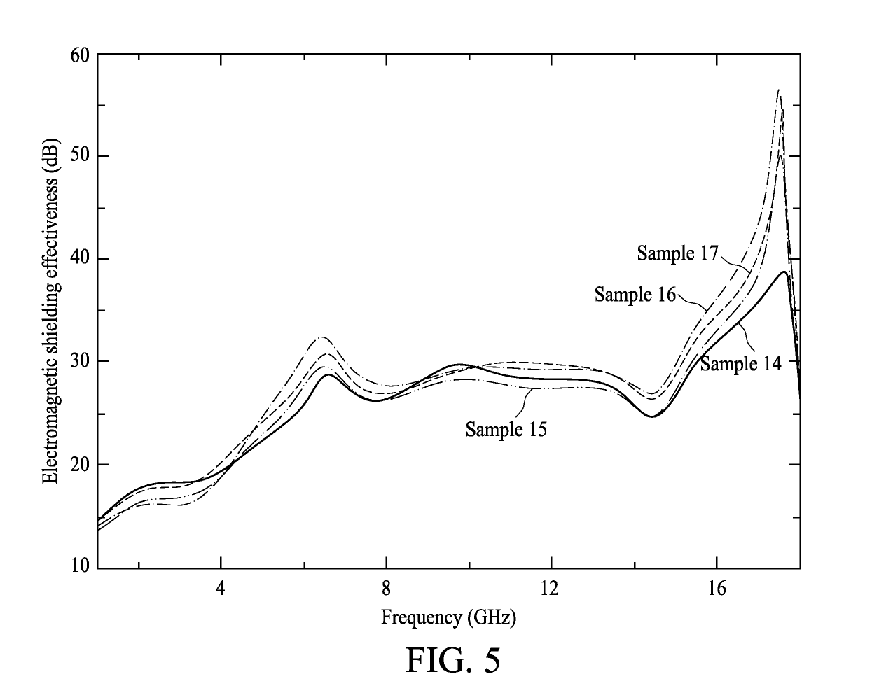

As illustrated in FIGS. 2 and 5, compared with the test results shown in FIG. 2, Samples 14 to 17 include higher amounts of silver nanowires so that the formed thin films can have lower surface resistivity. However, compared with the experiment results shown in FIGS. 2 and 5, it can be seen that thin films formed with Samples 14 to 17 do not have significantly improved electromagnetic shielding effectiveness because of their low surface resistivity.

For example, in comparison of Sample 5 and Sample 17, the thin film formed with Sample 5 exhibits electromagnetic shielding effectiveness of from 36 to 53 dB over a frequency range of from 6 to 16 GHz, while the thin film formed with Sample 17 exhibits low electromagnetic shielding effectiveness of from 9 to 52 dB over the same frequency range. With the increase of the concentration of nanowires, the increase of the diameters of nanoparticles, in a similar concentration can exhibit significant effect over high frequency spectrum.

In addition, as shown in FIG. 5, comparing the electromagnetic shielding effectiveness of the thin films formed using Samples 14 to 16, the electromagnetic shielding effectiveness is improved by increasing the content of iron oxide nanoparticles for the most frequency range. Compared with the thin film without including iron oxide nanoparticles, the thin film including 1.2 percent by weight iron oxide nanoparticles has improved electromagnetic shielding effectiveness. Similarly, when more iron oxide nanoparticles are added, for example to increase the concentration to 1.79 percent by weight (Sample 17), the electromagnetic shielding effectiveness of the thin film decreases. Thus, when iron oxide nanoparticles are from 300 to 700 nanometers in diameter, silver nanowires have aspect ratios of 200 to 300, and the thin film includes nanowires of greater than 3 percent by weight, the amount of the iron oxide nanoparticles is preferably in a range of from 0.1 to 3 percent by weight, more preferably in a range of from 0.2 to 2 percent by weight, and most preferably in a range of from 0.3 to 2 percent by weight.

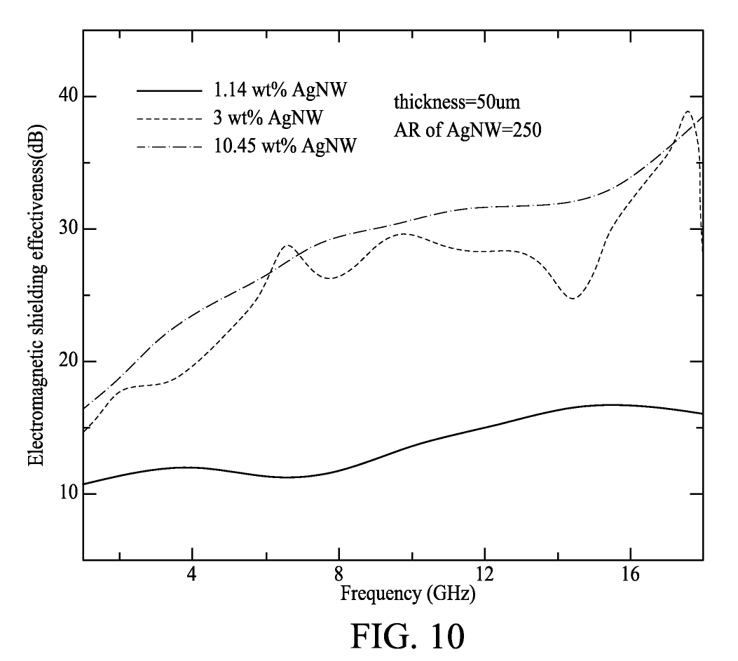

In addition, as indicated by the experiment results shown in FIGS. 2 and 3, using nanowires with high aspect ratios may increase the electromagnetic shielding effectiveness. Moreover, referring to FIG. 10, when the concentration of the nanowires in a thin film is increased to a level greater than 3 percent by weight, the electromagnetic shielding effectiveness of the thin film is not significantly improved. However, if metal nanoparticles of different sizes or high magnetic permeability nanoparticles of different sizes are added to the thin film, the optical path lengths of high frequency electromagnetic waves in the thin film can be changed so as to improve the electromagnetic shielding effectiveness.

### Experiment 5

Table 5 below shows compositions (Samples 18 to 21) each including 10.45 percent by weight silver nanowires and iron oxide nanoparticles in a specific amount of from 0 to 1.87 percent by weight based on the total weight of the composition taken as 100 percent, wherein the silver nanowires have an aspect ratio of 250 and the diameters of the iron oxide nanoparticles are around 30 nanometers. After mixing, Samples 18 to 21 are used to separately form a thin film with a thickness of 50 micrometers for testing electromagnetic shielding effectiveness. The compositions include a polymer material that includes polymethyl methacrylate solution. Based on the total weight of the polymer material taken as 100 percent, Polymethyl methacrylate can comprise from 45 to 55 percent by weight of the polymer material, and water can comprise from 45 to 55 percent by weight of the polymer material.

TABLE 5

| | iron oxide nano- | | |
|---|---|---|---|
| | particles with | | |
| | a diameter of | silver nanowires with | polymethyl |
| | 30 nanometers | an aspect ratio of 250 | methacrylate |
| | (weight %) | (weight %) | (weight %) |
| Sample 18 | 0 | 10.45 | 44.775 |
| Sample 19 | 0.66 | 10.45 | 44.445 |
| Sample 20 | 1.33 | 10.45 | 44.11 |
| Sample 21 | 1.87 | 10.45 | 43.84 |

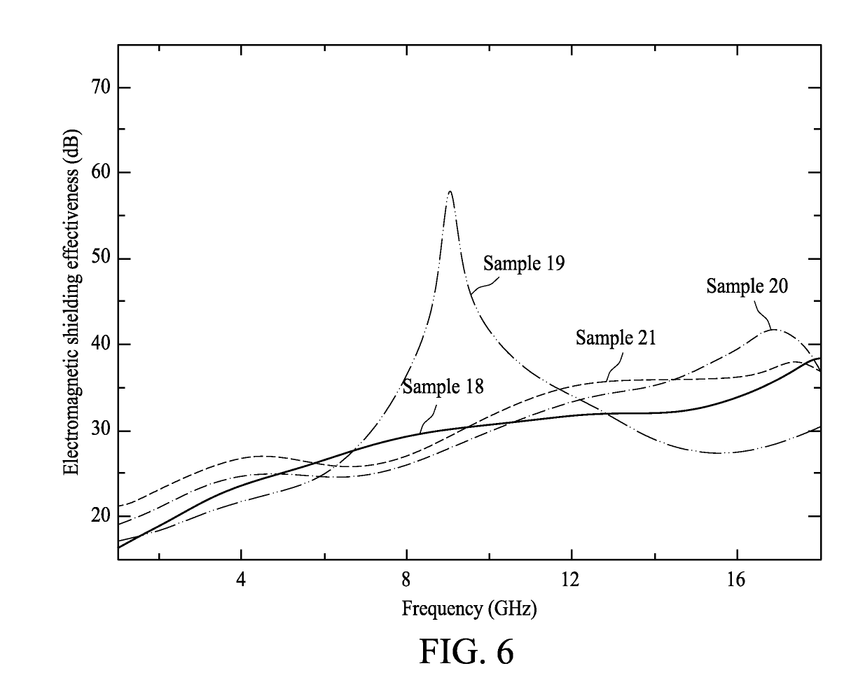

As illustrated in FIGS. 2 and 6, compared with the test results shown in FIG. 2, Samples 18 to 21 include higher amounts of silver nanowires so that thin films formed using Samples 18 to 21 can have lower surface resistivity. However, compared with the experiment results shown in FIGS. 2 and 5, it can be seen that thin films formed with Samples 18 to 21 do not have significantly improved electromagnetic shielding effectiveness because of their low surface resistivity.

For example, in comparison of Sample 5 and Sample 21, the thin film formed with Sample 5 exhibits electromagnetic shielding effectiveness of 36 to 48 dB over a frequency range of 4 to 16 GHz, while the thin film formed with Sample 21 exhibits low electromagnetic shielding effectiveness of 25 to 37 dB over the same frequency range.

Further, as indicated by the electromagnetic shielding effectiveness test results for the thin films formed with Samples 18 to 21, the electromagnetic shielding effectiveness is improved with the increase of the content of iron oxide nanoparticles, whereas compared with the thin film without including iron oxide nanoparticles, the thin film including 1.87 percent by weight iron oxide nanoparticles has preferable electromagnetic shielding effectiveness. Therefore, when iron oxide nanoparticles are from 10 to 50 nanometers in diameter, silver nanowires have aspect ratios of 200 to 300, and the thin film includes nanowires in a concentration of 10.45 percent by weight, the amount of the iron oxide nanoparticles is preferably from 0.4 to 2.6 percent by weight, more preferably from 0.6 to 2.4 percent by weight, and most preferably from 1 to 2 percent by weight.

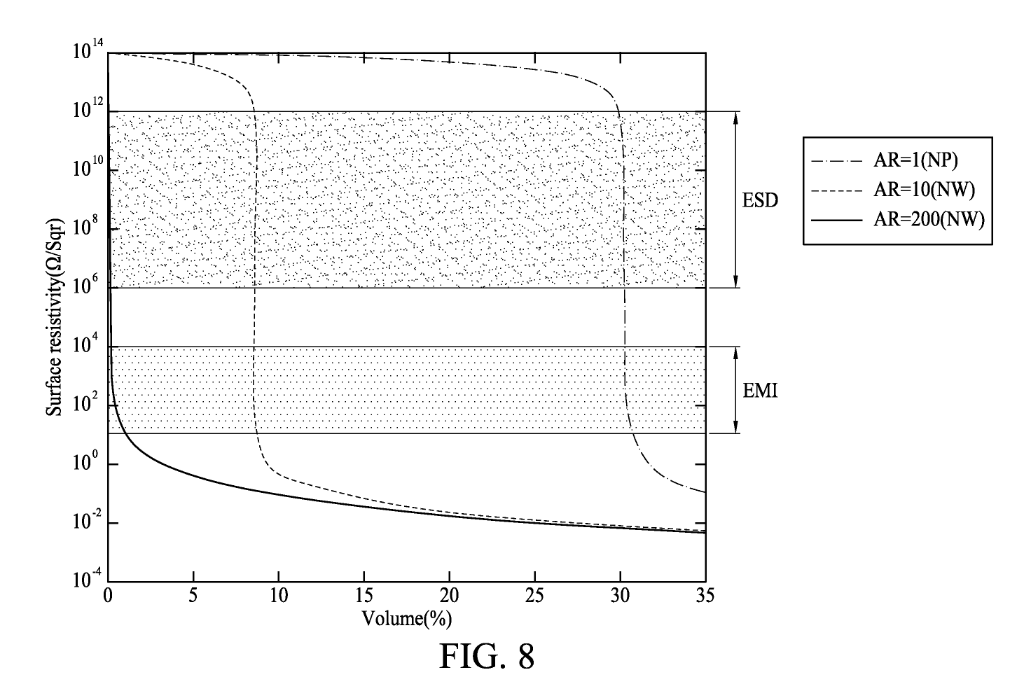

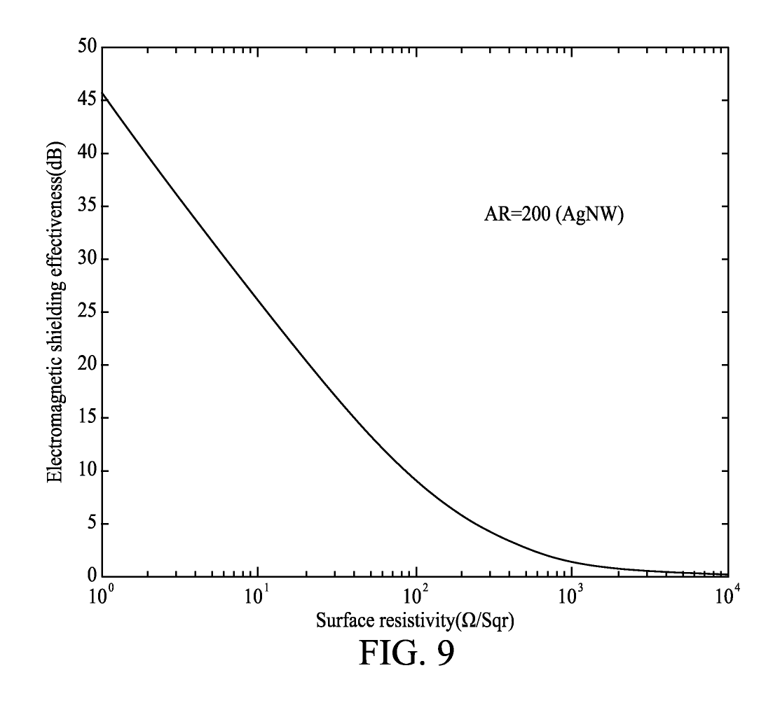

Thus, as shown in FIGS. 5 and 6, and further in FIGS. 8 to 10, after nanowires are increased to a certain level, the improvement of the electromagnetic shielding effectiveness is not obvious by a further addition of nanowires. Instead, by adding a certain concentration of nanoparticles, the electromagnetic shielding effectiveness over high frequency spectrum can be unexpectedly improved.

### Experiment 6

Table 6 below shows compositions (Samples 22 to 25) each including 1.14 percent by weight silver nanowires and silver nanoparticles in a specific amount of from 0 to 1.99 percent by weight based on the total weight of the composition taken as 100 percent, and Sample 26 which includes 7.65 percent by weight silver nanoparticles and does not include silver nanowires, wherein the silver nanowire has an aspect ratio of 250 and the diameter of the silver nanoparticle is around 100 nanometers. After mixing, Samples 22 to 26 are used to separately form a thin film with a thickness of 50 micrometers for testing electromagnetic shielding effectiveness. The compositions include a polymer material that includes polymethyl methacrylate solution. Based on the total weight of the polymer material taken as 100 percent, Polymethyl methacrylate can comprise from 45 to 55 percent by weight of the polymer material, and water can comprise from 45 to 55 percent by weight of the polymer material.

TABLE 6

| | silver nano- | | |
|---|---|---|---|
| | particles with | | |
| | a diameter of | silver nanowires with | polymethyl |
| | 100 nanometers | an aspect ratio of 250 | methacrylate |
| | (weight %) | (weight %) | (weight %) |
| Sample 22 | 0 | 1.14 | 49.43 |
| Sample 23 | 0.66 | 1.14 | 49.1 |
| Sample 24 | 1.33 | 1.14 | 48.765 |
| Sample 25 | 1.99 | 1.14 | 48.435 |
| Sample 26 | 7.65 | 0 | 46.175 |

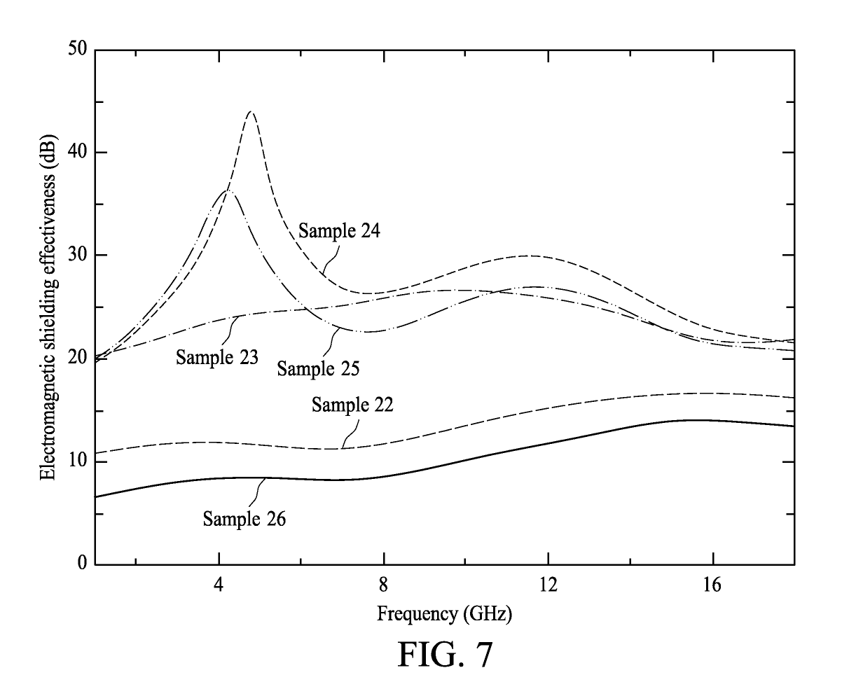

As illustrated in FIG. 7, compared with the experiment results shown in FIG. 4, Samples 23 to 26 include electrically conductive silver nanoparticles so that thin films formed using Samples 23 to 26 can have lower surface resistivity. However, compared with the experiment results shown in FIGS. 4 and 7, it can be seen that thin films formed with Samples 23 to 26 do not have preferable electromagnetic shielding effectiveness because of their low surface resistivity.

For example, in comparison of Sample 12 and Sample 24, the thin film formed with Sample 12 exhibits electromagnetic shielding effectiveness of 18 to 29 dB over the demonstrated frequency range, while the thin film formed with Sample 29 exhibits electromagnetic shielding effectiveness of 19 to 30 dB over the same frequency range. Both samples exhibit nearly identical electromagnetic shielding effectiveness except around the frequency of 4.8 GHz, at which a resonant mode occurs with the thin film formed with Sample 24. According to the above-mentioned experiment results, thin films added with silver nanoparticles and thin films added with magnetically permeable dielectric nanoparticles exhibit identical electromagnetic shielding effectiveness.

Therefore, when silver nanoparticles are from 80 to 120 nanometers in diameter and silver nanowires have aspect ratios of 200 to 300, the amount of the silver nanoparticles is preferably in a range of 0.5 to 2.5 percent by weight, and more preferably in a range of 0.7 to 2 percent by weight.

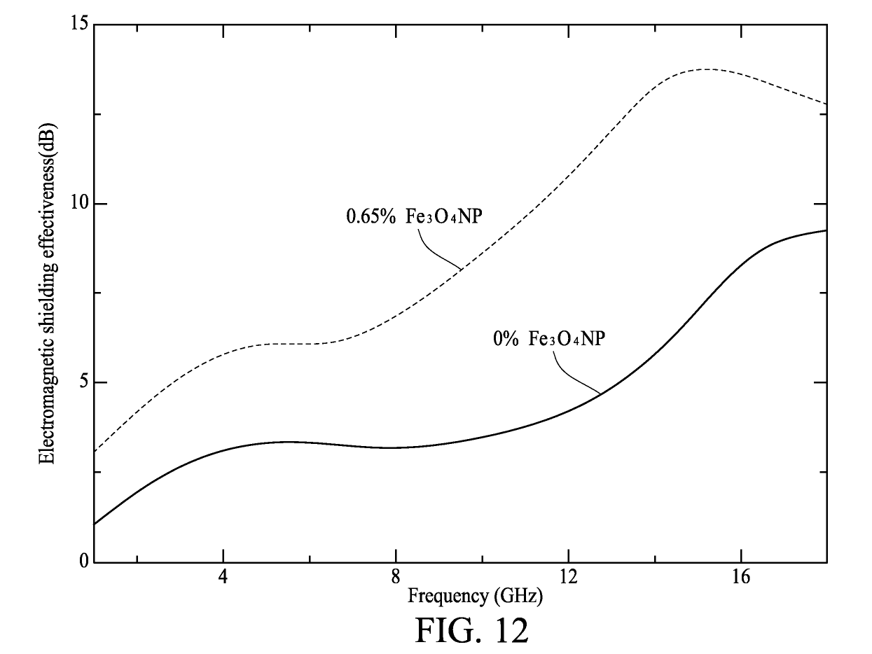

Further, in comparison of electromagnetic shielding effectiveness test results for the thin films formed with Samples 22 to 25, the electromagnetic shielding effectiveness of the thin film including only nanowires is better than that of the thin film including only nanoparticles. The electromagnetic shielding effectiveness is improved with the increase of the content of silver nanoparticles, and if electrically conductive nanoparticles are used to replace magnetically permeable nanoparticles, both types of thin films can have a certain level of electromagnetic shielding effectiveness. FIG. 12 shows test results of the electromagnetic shielding effectiveness of two thin films, wherein the two thin films are prepared using a carrier, which is bisphenol A type epoxy resin BE188 manufactured by Chang Chun Plastics Co., Ltd., Taiwan. The two thin films are manufactured separately using two compositions, wherein each of the two compositions includes 2.06 percent by weight nanowires with an aspect ratio of 80, and one composition further includes 0.65 percent by weight nanoparticles with a diameter of about 50 nanometers and the other composition does not include nanoparticles. According to the experiment results, it can be seen that after the carrier, the material of which is changed from acrylic resin to bisphenol A type epoxy resin BE188, has nanoparticles added, the thin film formed with the mixture of the carrier and the nanoparticles is improved. Thus, the unexpected improvement to the electromagnetic shielding effectiveness due to the addition of a certain concentration ratio of nanoparticles is not affected by using different polymer material.

Thin films formed using the presently disclosed composition including nanowires and nanoparticles can exhibit excellent electromagnetic shielding effectiveness.

TABLE 7

| | | EMI |
|---|---|---|
| | | shielding |
| Item | composition (weight %) | effect |
| Sample 4 | nanowire plus nanoparticles < | >40 dB |
| | 2% | |
| Commercial product B | graphite or electrically | <30 dB |
| (EMR-PROTECTION) | conductive particles > 40% | |
| provided by YShield | (solid content) | |
| EMR-Protection | | |
| Commercial product C | graphite or electrically | <30 dB |
| (ECOS E.M.R.-E.L.F. | conductive particles > 40% | |
| RADIATION SHIELDING | (solid content) | |
| WALL PAINT) provided by | | |
| Eco Organic Paints | | |

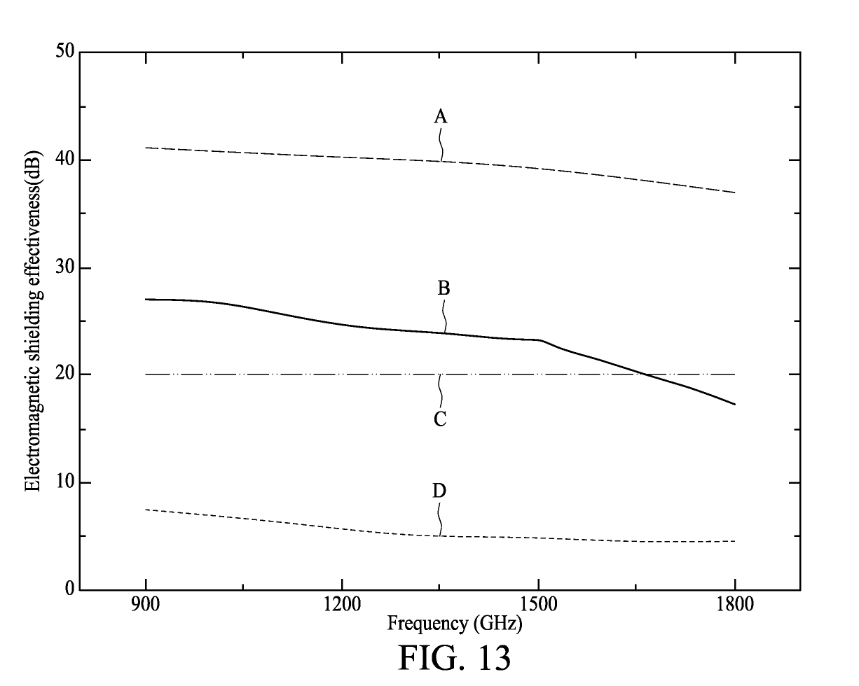

As shown in Table 7 and FIG. 13, compared with the thin films formed using commercial products B and C including conventional round metal particles, the thin films including nano-structure and formed using Sample 4 of the present disclosure can provide better EMI shielding. Furthermore, those commercial products need the addition of high amounts of particles, and in comparison, the composition A of the present disclosure needs only the addition of a low amount of nano-material and can provide better EMI shielding.

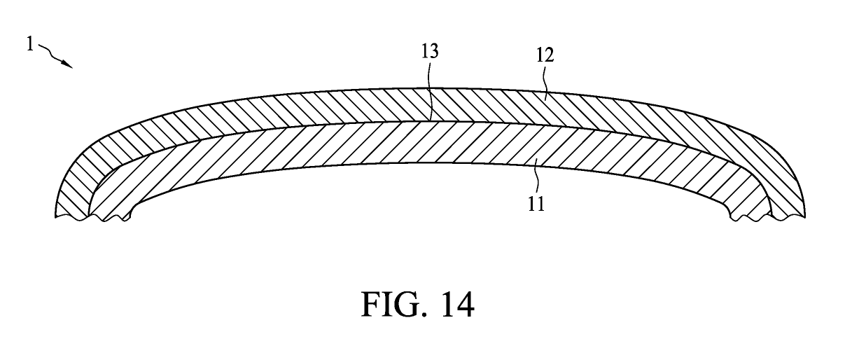

Referring to FIG. 14, the present disclosure provides an electromagnetic shielding device 10. The electromagnetic shielding device 10 comprises a body member 11 including a surface 13 and a thin film 12 formed on the surface 13 for providing EMI shielding. The thin film 12 may comprise a plurality of metal nanowires and a plurality of nanoparticles. The plurality of metal nanowires and the plurality of nanoparticles are uniformly dispersed within the thin film 12 and mutually mixed with each other, wherein the metal nanowires comprise from 1 to 95 percent by weight based on the total weight of the thin film 12 taken as 100 percent, and the nanoparticles comprise from 0.5 to 60 percent by weight based on the total weight of the thin film 12 taken as 100 percent. The body member 11 can be any target that needs to be coated by the thin film 12 for EMI shielding. For example, the body member 11 can be wires, plates, polymer films or device shells.

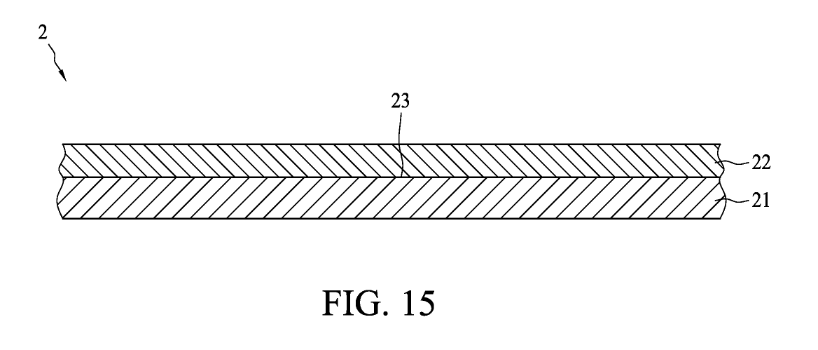

Referring to FIG. 15, the present disclosure further provides an anti-electrostatic device 20. The anti-electrostatic device 20 comprises a substrate 21 having a surface 23 and a thin film 22 formed on the surface 23 for providing anti-electrostatic protection. The thin film 22 may comprise a plurality of metal nanowires and a plurality of nanoparticles. The plurality of metal nanowires and the plurality of nanoparticles are uniformly dispersed within the thin film 22 and mixed with each other, wherein the metal nanowires comprise from 1 to 95 percent by weight based on the total weight of the thin film 22 taken as 100 percent, and the nanoparticles comprise from 0.5 to 60 percent by weight based on the total weight of the thin film 22 taken as 100 percent.

In summary, the addition of a suitable amount of nanoparticles to a composition including metal nanowires can improve the electromagnetic shielding effectiveness of the thin film formed using the composition. According to the results of the above-mentioned experiments, it is believed that based on the total weight of the composition taken as 100 percent, the concentration of the metal nanowires can be in a range of from 1 to 95 percent by weight. Preferably, the amount of the metal nanowires can be from 1 to 11 percent by weight. More preferably, the amount of the metal nanowires can be from 1 to 3 percent by weight. Furthermore, the amount of magnetically permeable or metal nanoparticles can be in a range of from 0.1 to 60 percent by weight, from 0.1 to 10 percent by weight, from 0.5 to 10 percent by weight, or from 0.5 to 2 percent by weight.

In addition, the addition of large amounts of magnetically permeable or metal nanoparticles to the composition including metal nanowires cannot significantly contribute to the improvement of the electromagnetic shielding effectiveness. Further, compared with the thin films added with metal nanowires or metal nanoparticles for increasing electrical conductivity, the thin films added with magnetically permeable nanoparticles can exhibit better improvement of the electromagnetic shielding effectiveness.

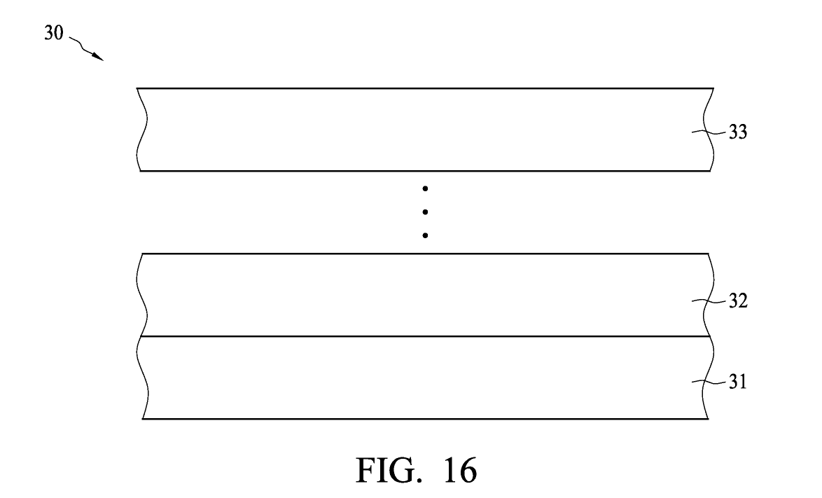

FIG. 16 is a view showing an electromagnetic shielding structure 30 according to one embodiment of the present invention. The electromagnetic shielding structure 30 comprises a target 31 and a thin film 32. The method of manufacturing the electromagnetic shielding structure 30 comprises providing a target 31, forming a thin film 32 on the target 31 by coating or spraying, and heating the thin film 32 at a temperature in a range of from 50 to 250 degrees Celsius by introducing light on the thin film 32 or using an oven. The compositions of the thin films 32 are demonstrated in Table 8. The compositions are configured to be coated or sprayed. The compositions may comprise silver nanowires and a polymer material. In some embodiments, the compositions further comprise nanoparticles. The polymer material may comprise polyurethane and water, wherein based upon the total weight of the composition taken as 100 percent, the polyurethane comprises from 45 to 55 percent by weight of the composition, and the water comprises from 45 to 55 percent by weight of the composition.

TABLE 8

| | | iron oxide nano- | |
|---|---|---|---|
| | silver nano- | particles with | |
| | particles with | a diameter of | |
| | an aspect ratio of 150 | 80 nanometers | polyurethane |
| | (weight %) | (weight %) | (weight %) |
| Sample 27 | 2.43 | 1.45 | 48.06 |
| Sample 28 | 3.49 | 2.18 | 47.165 |
| Sample 29 | 2.1 | 0.55 | 48.675 |
| Sample 30 | 1.09 | 3.69 | 47.61 |

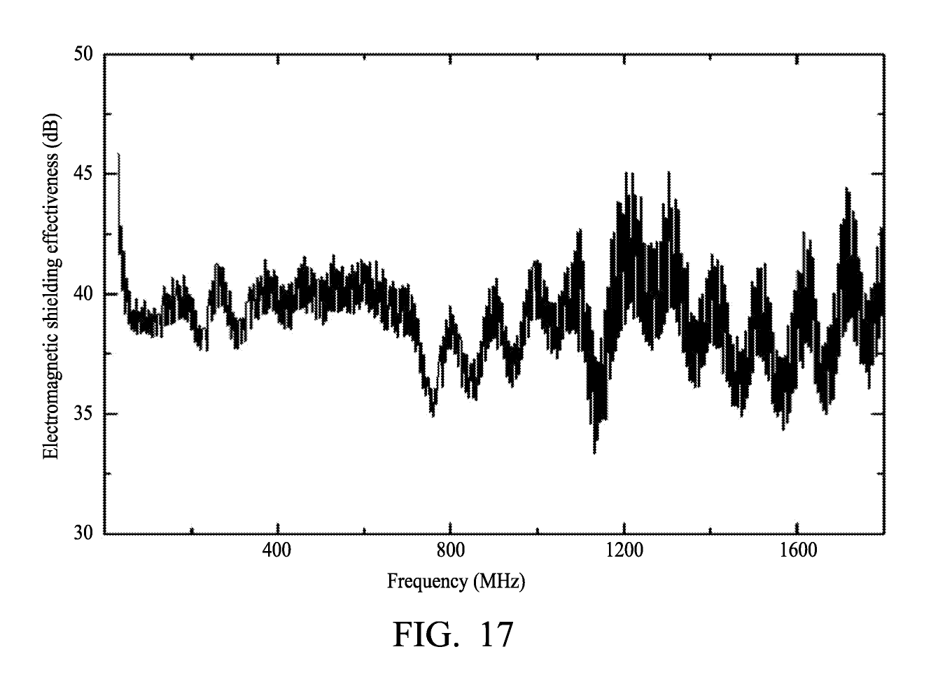

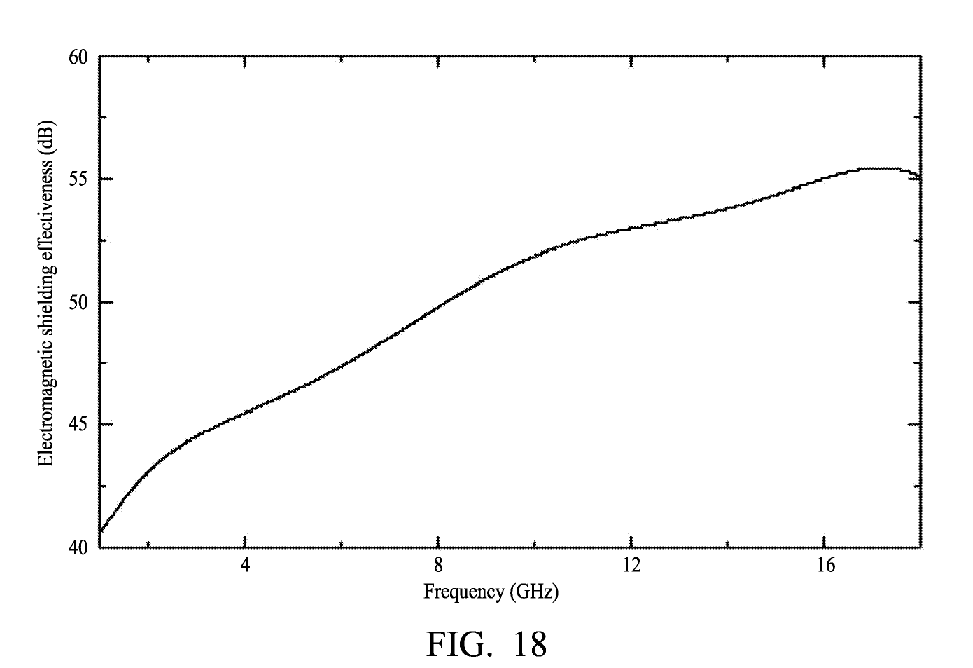

FIG. 17 is a diagram showing a shielding effectiveness measurement, over a frequency range of from 1 to 1800 MHz, of a thin film formed by a mixture including 2.43 percent by weight silver nanowires and 1.45 percent by weight iron oxide particles according to one embodiment of the present invention. FIG. 18 is a diagram showing a shielding effectiveness measurement, over a frequency range of from 1 to 18 GHz, of a thin film formed by a mixture including 2.43 percent by weight silver nanowires and 1.45 percent by weight iron oxide particles according to one embodiment of the present invention. Sample 27 is coated on the target and then heated at 80 degrees Celsius for 5 minutes to form a thin film with a thickness of 50 micrometers. Next, the shielding effectiveness of the thin film is measured. From the results shown in FIGS. 17 and 18, after the thin film is heated at 80 degrees Celsius for 5 minutes, the shielding effectiveness of the thin film over a frequency range of from 1 to 1800 MHz is significantly improved, and the shielding effectiveness is increased to a level of above 40 dB.

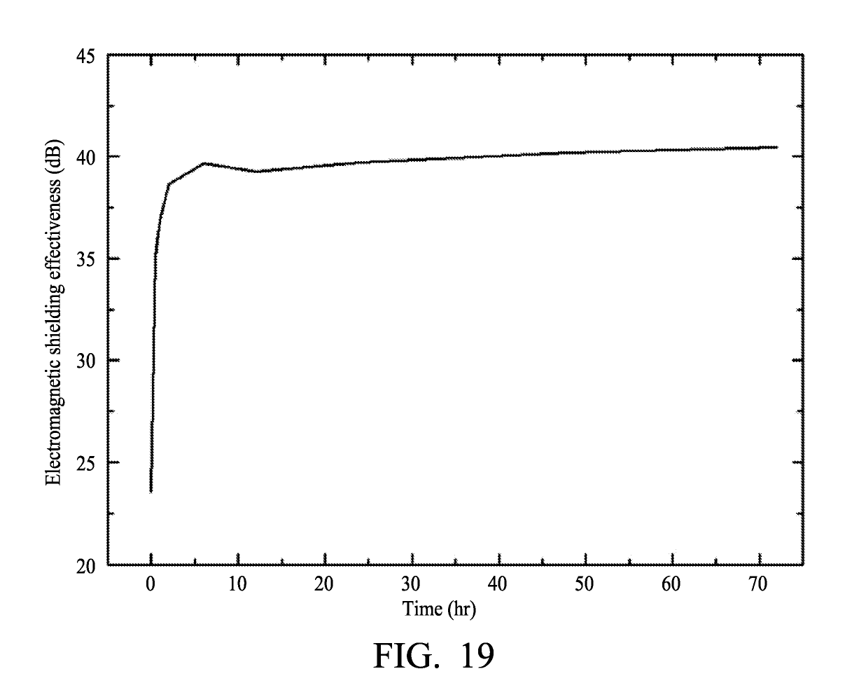

FIG. 19 is a diagram showing the relationship between the heating time and the shielding effectiveness of thin films formed by a mixture including 2.43 percent by weight silver nanowires and 1.45 percent by weight iron oxide particles according to one embodiment of the present invention. Sample 27 is coated on the target, and is then heated at 80 degrees Celsius for 5 minutes to form a thin film with a thickness of 30 micrometers. Several thin films are further heated at 150 degrees Celsius for different periods of time. The shielding effectiveness of the thin films heated for different periods of time are measured, and the results are demonstrated in FIG. 19. As shown in FIG. 19, when a thin film is heated for more than one hour, its shielding effectiveness can be increased up to 10 dB or above. If a thin film is heated at 150 degrees Celsius for 72 hours, its shielding effectiveness can be increased up to 4 dB or above.

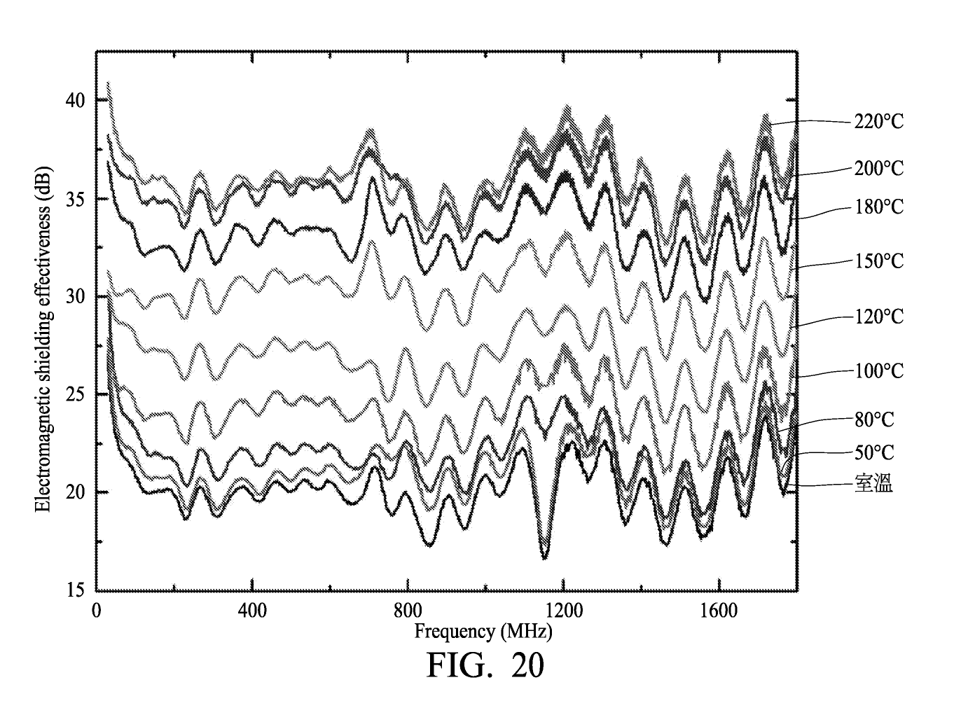

FIG. 20 is a diagram showing the relationship between the heating time and the shielding effectiveness of thin films formed by a mixture including 2.43 percent by weight silver nanowires and 1.45 percent by weight iron oxide particles according to one embodiment of the present invention. Sample 27 is coated on a target and heated at 80 degrees Celsius for 5 minutes to form a thin film of 20 micrometers in thickness. Thin films are heated at different temperatures for one hour. Next, the shielding effectiveness of the thin films heated at different temperatures is measured, and the results are demonstrated in FIG. 20. As shown in FIG. 20, the shielding effectiveness of a thin film increases as the temperature for heating the thin film increases. Thus, the shielding effectiveness of a thin film can be adjusted by applying different heating temperatures. In addition, the heated thin films shown in FIG. 20 are tested by the pencil hardness test, getting a B rating, and tested by an adhesion test (adhesiveness of finish by cross cutting with scotch tape test), getting a rating of 4B.

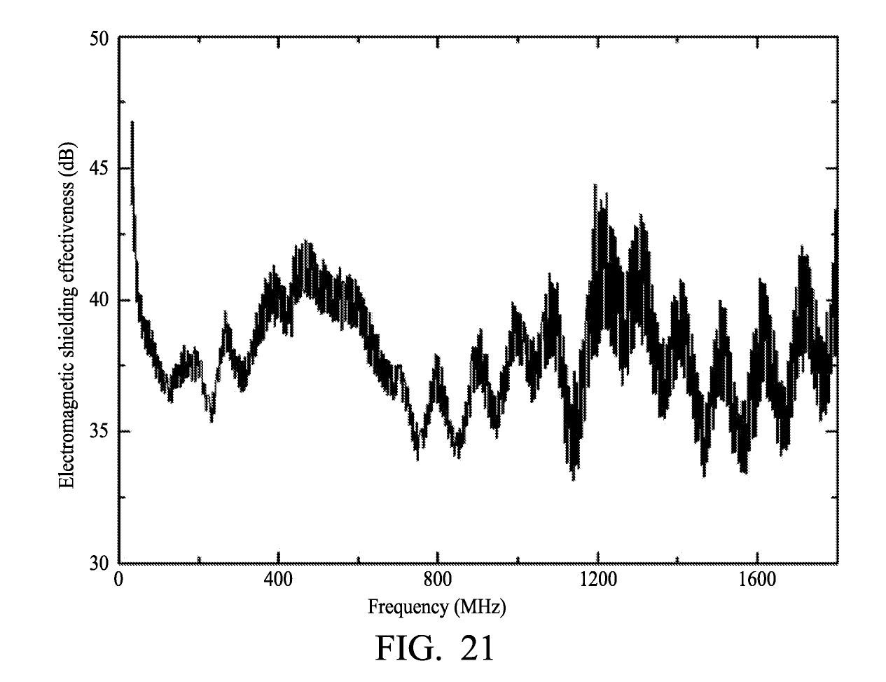

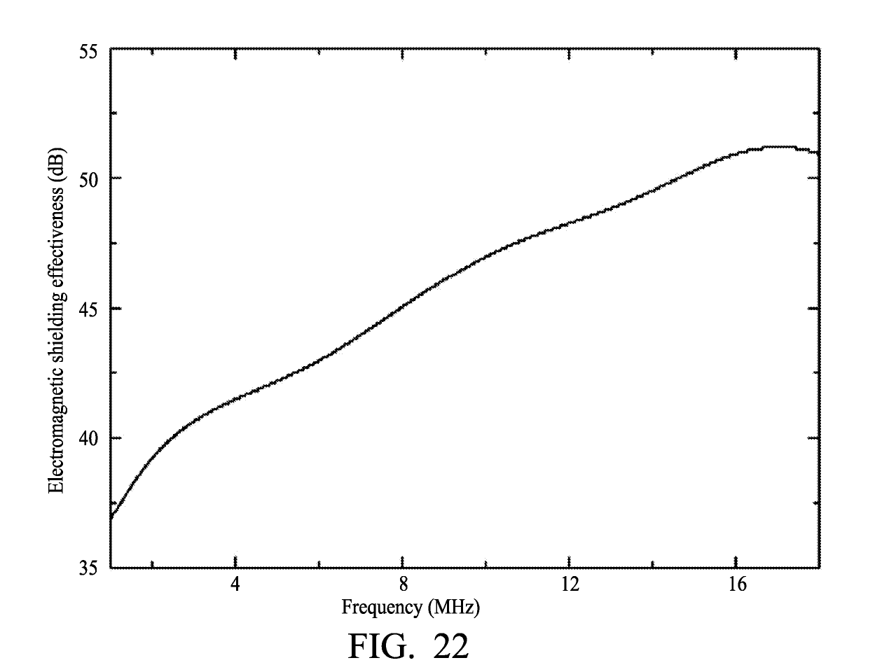

FIG. 21 is a diagram showing a shielding effectiveness measurement, over a frequency range of from 1 to 1800 MHz, of a thin film formed by a mixture including 3.49 percent by weight silver nanowires and 2.18 percent by weight iron oxide particles according to one embodiment of the present invention. FIG. 22 is a diagram showing a shielding effectiveness measurement, over a frequency range of from 1 to 18 GHz, of a thin film formed by a mixture including 3.49 percent by weight silver nanowires and 2.18 percent by weight iron oxide particles according to one embodiment of the present invention. Sample 28 is coated on the target and then heated at 80 degrees Celsius for 5 minutes to form a thin film with a thickness of 80 micrometers. Next, the shielding effectiveness of the thin film is measured. From the results shown in FIGS. 21 and 22, after the thin film is heated at 80 degrees Celsius for 5 minutes, the shielding effectiveness of the thin film over a frequency range of from 1 to 1800 MHz is significantly improved, and the shielding effectiveness is increased to a level of above 40 dB. In addition, due to mixing of iron oxide particles and silver nanoparticles, thin films can have the effects of multiple scattering and absorbing; thus a better shielding effectiveness can be achieved.

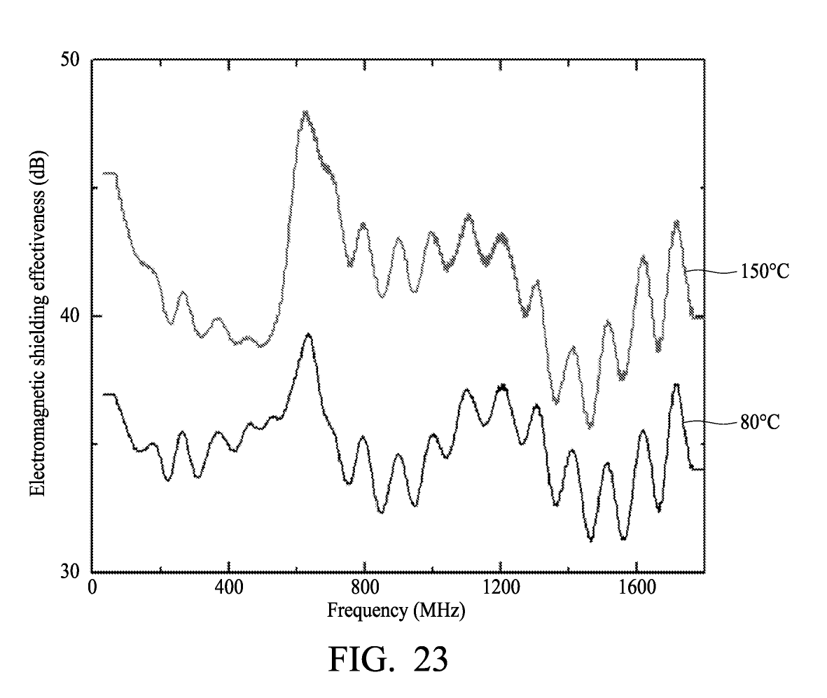

FIG. 23 is a diagram showing shielding effectiveness measurements, over a frequency range of from 1 to 1800 MHz, of thin films formed by a mixture including 2.1 percent by weight silver nanowires and 0.55 percent by weight iron oxide particles and heated by different heating times and temperatures according to one embodiment of the present invention. Sample 29 is coated on a target and then heated at 80 degrees Celsius for 5 minutes to form a thin film with a thickness of 70 micrometers. The shielding effectiveness of the thin films are measured and shown in FIG. 23. Further, thin films are placed in an oven and heated again at 150 degrees Celsius for 24 hours. The shielding effectiveness measuring method is subsequently performed, and the results are shown in FIG. 23. As shown by the results of FIG. 23, after thin films are heated at 150 degrees Celsius for 24 hours, their shielding effectiveness can be increased by 10 dB.

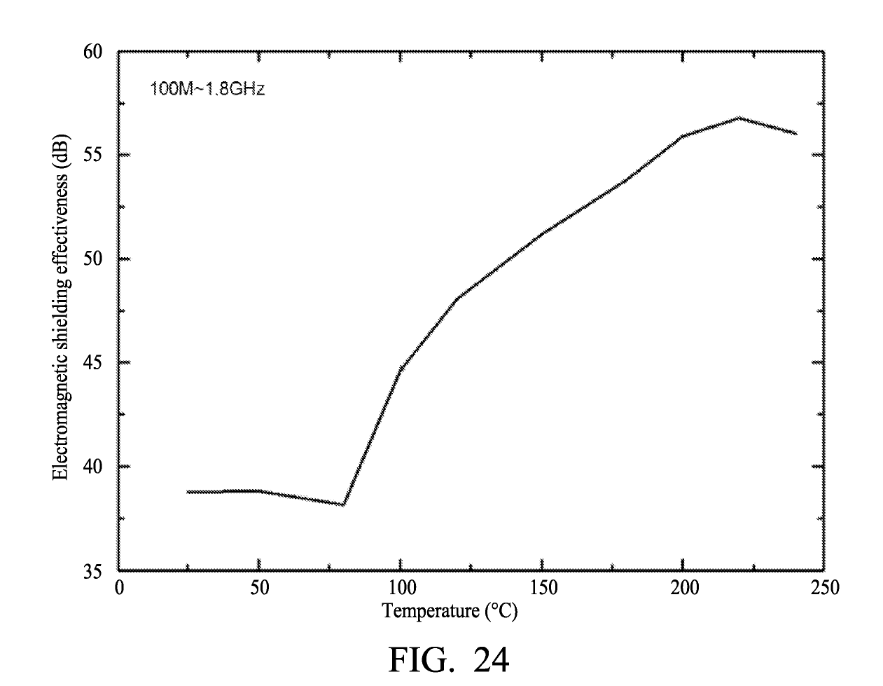

FIG. 24 is a diagram showing shielding effectiveness measurements, over a frequency range of from 100 to 1800 MHz, of a thin film formed by a mixture including 1.09 percent by weight silver nanowires and 3.69 percent by weight iron oxide particles and heated for different heating times according to one embodiment of the present invention. Sample 30 is coated on a target and heated at 80 degrees Celsius for 5 minutes to form a thin film with a thickness of 30 micrometers. Thereafter, thin films are heated at different temperatures for one hour. Next, the shielding effectiveness of the thin films is measured, and the results are shown in FIG. 24. As shown in FIG. 24, when the heating temperature is above 80 degrees Celsius, the shielding effectiveness of the thin film can be increased to over 40 dB.

Referring back to FIG. 16, the electromagnetic shielding structure 30 can comprise a target 31, a thin film 32, and an adhesive layer 33, wherein the thin film 32 is disposed on the target 31, and the adhesive layer 33 is disposed on the thin film 32. In one embodiment, the adhesive layer 33 comprises a pressure sensitive adhesive. In addition, in another embodiment, the electromagnetic shielding structure 30 may further include at least one second thin film (not shown), wherein the thin film 32 and the second thin film are stacked on each other. The second thin film can be between the adhesive layer 33 and the thin film 32. The thin film 32 and the second thin film can separately include nanoparticles and metal nanowires.

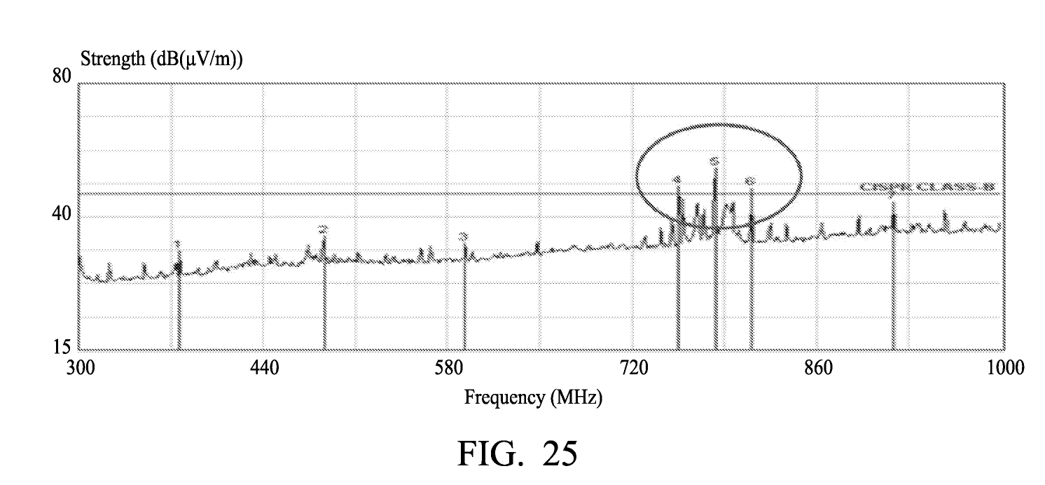

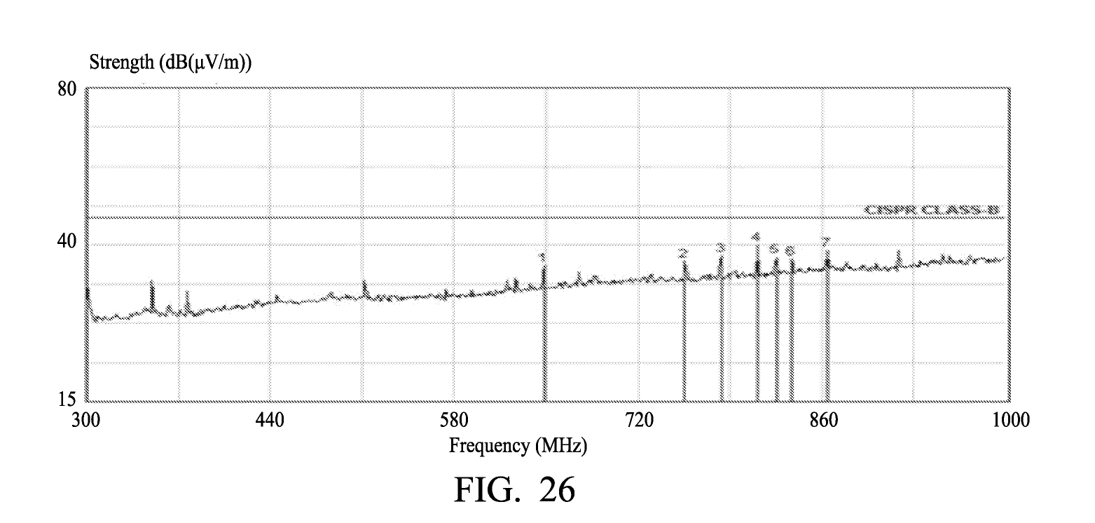

FIG. 25 is a diagram representing the relationship between frequency and the strength of electromagnetic radiation measured from a hard disc without an electromagnetic shielding film. FIG. 26 is a diagram representing the relationship between frequency and the strength of electromagnetic radiation measured from a hard disc coated with an electromagnetic shielding film (Sample 31). The result of FIG. 25 is from measuring a hard disc in accordance with EU-EMC Directive (2004/108/EC) EN 55022 class B, wherein electromagnetic radiation emissions at frequencies of 377, 486, and 593 MHz (separately indicated by number 4, 5, and 6) exceed a standard level. Sample 31 is coated on a hard disc to form a thin film with a thickness of 50 micrometers. After the thin film is dried, the hard disc is measured and the electromagnetic radiation emissions all comply with the requirements of EU-EMC Directive (2004/108/EC) EN 55022 class B. Thus, the thin film formed using Sample 31 can reduce EMI. Samples 31 and 32 include a polymer material including polyurethane solution comprising 45-55 weight percent of polyurethane and 45-55 weight percent of water.

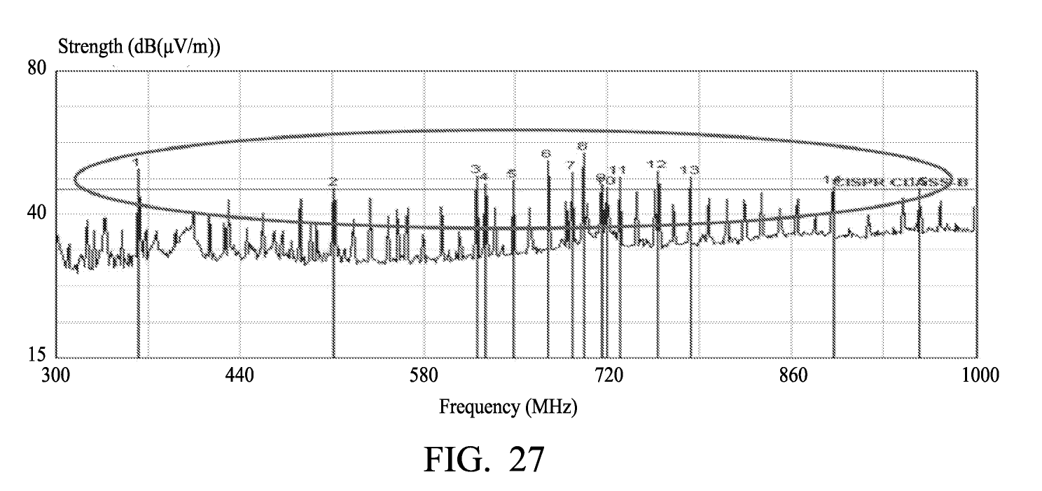

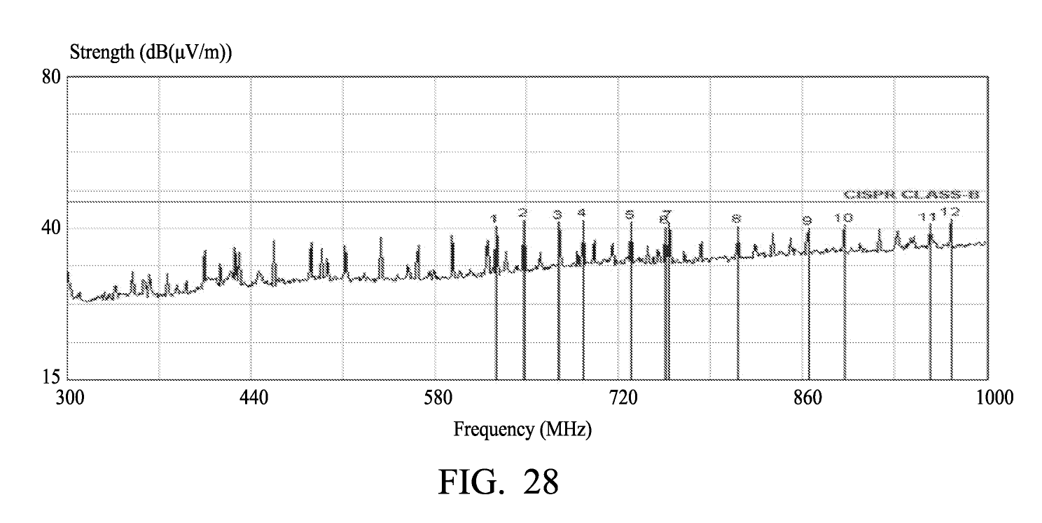

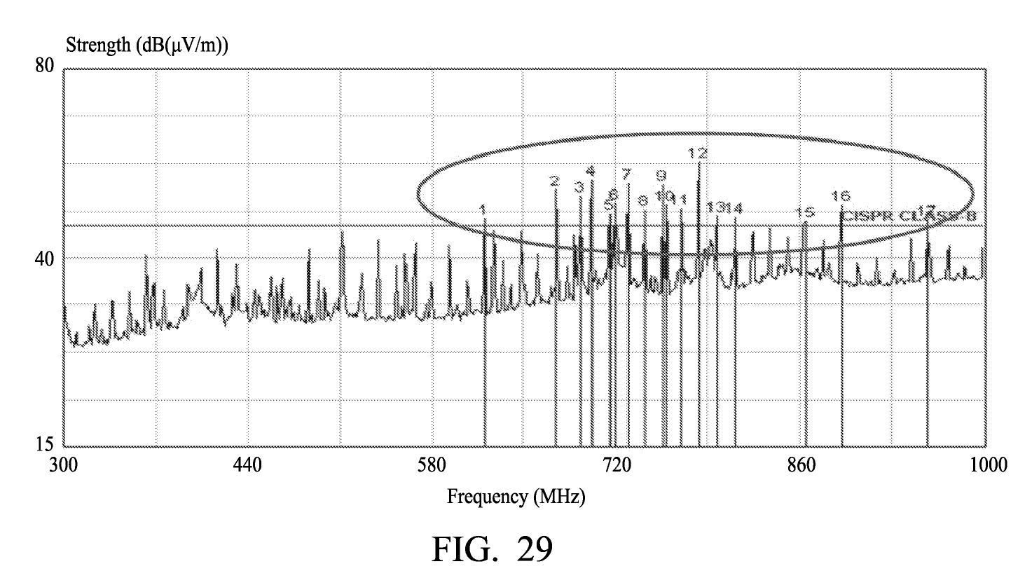

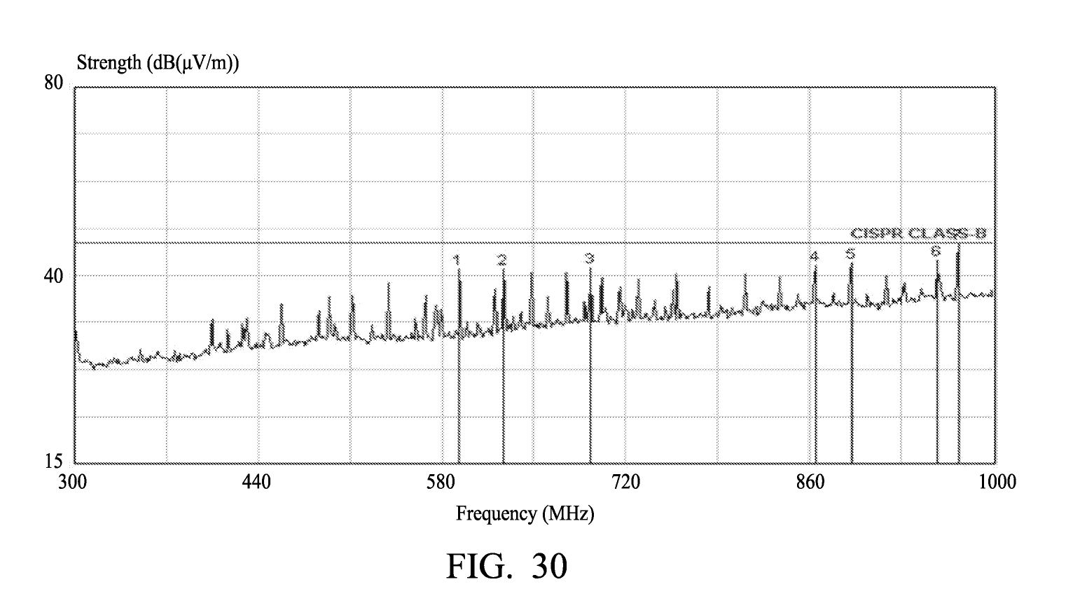

TABLE 9

| | Sample 31 | Sample 32 |
|---|---|---|
| nanowires (with aspect ratio | 2.61 weight percent | 2.71 weight percent |
| of 150) | | |
| iron oxide particles (with | 0.81 weight percent | 0.81 weight percent |
| particle size of 80 | | |
| nanometers) | | |
| polyurethane solution (weight %) | 5.07 | 5.71 |
| surface resistivity (Ω/sqr) | 7.28 | 4.36 |
| viscosity (cps) | 289.74 | 3765.83 |
| measurements, before | radiation exceeds the | radiation in the horizontal |
| coating, comply with | requirements at 3 frequencies | direction exceeds the |
| EU-EMC Directive | (FIG. 25) | requirements at 15 |
| (2004/108/EC) EN 55022 | | frequencies (FIG. 27). |
| class B? | | radiation in the vertical |
| | | direction exceeds the |
| | | requirements at 17 |
| | | frequencies (FIG. 29). |
| measurements, after coating, | coated product: hard disc | coated product: video player |
| comply with EU-EMC | coated thickness: 50 | coated thickness: 30 |
| Directive (2004/108/EC) EN | micrometers | micrometers |
| 55022 class B? | radiation is under the | radiation is under the |
| | requirements at all | requirements at all |
| | frequencies (FIG. 26) | frequencies in the horizontal |
| | | direction (FIG. 28) |
| | | radiation is under the |
| | | requirements at all |
| | | frequencies in the vertical |
| | | direction (FIG. 30) |

FIG. 27 is a diagram representing the relationship between frequency and strength of electromagnetic radiation measured in the horizontal direction from a video player without an electromagnetic shielding film. FIG. 29 is a diagram representing the relationship between frequency and strength of electromagnetic radiation measured in the vertical direction from a video player without an electromagnetic shielding film. FIG. 28 is a diagram representing the relationship between frequency and strength of electromagnetic radiation measured in the horizontal direction from a video player coated with an electromagnetic shielding film (Sample 32). FIG. 30 is a diagram representing the relationship between frequency and strength of electromagnetic radiation measured in the vertical direction from a video player coated with an electromagnetic shielding film (Sample 32). In accordance with EU-EMC Directive (2004/108/EC) EN 55022 class B, measurements are performed in the horizontal and vertical directions on video players without being coated with an electromagnetic shielding film. It can be found that radiations at 15 and 17 frequencies exceed the requirements of the standard. However, an electromagnetic shielding film with a thickness of less than 50 micrometers is formed on the video player by Sample 32. The thin film is dried and tested, and it can be seen that the video player complies with the EU-EMC Directive (2004/108/EC) EN 55022 class B. Thus, the thin film formed by the Sample 32 of the present disclosure offers EMI shielding over a broad frequency range.

Conventionally, the shielding effectiveness and the conductivity are positively correlated. However, according to the experiment results for Samples 31 and 32, it can be seen that when electrically conductive material is added to a certain critical level, the change of the electrically conductive is limited.

Samples 31 and 32 comprise a polymer material including polyurethane and water, wherein based on the total weight of the polymer material taken as 100 percent, the polyurethane comprises from 45 to 55 percent by weight of the polymer material, and the water comprises from 45 to 55 percent by weight of the polymer material.

In summary, the disclosure provides a method of thermally treating an electromagnetic shielding film including nano-material so as to increase the shielding effectiveness of the thin film. Therefore, the thickness of the thin film can be reduced while not compromising its shielding effectiveness.

The above-described exemplary embodiments are intended to be illustrative only. Those skilled in the art may devise numerous alternative embodiments without departing from the scope of the following claims.

We claim:

1. An electromagnetic shielding composition, comprising:
a carrier;
a plurality of metal nanowires dispersed within the carrier and comprising from 1 to 95 percent based upon the total weight of the electromagnetic shielding composition taken as 100 percent by weight; and
a plurality of nanoparticles dispersed within the carrier and comprising from 0.1 to 60 percent based upon the total weight of the electromagnetic shielding composition taken as 100 percent by weight.

2. The electromagnetic shielding composition of claim 1, wherein the nanoparticle comprises metal or metal oxide, and the nanoparticles comprise from 0.5 to 20 percent by weight of the electromagnetic shielding composition.

3. The electromagnetic shielding composition of claim 1, wherein the nanoparticle comprises gold, silver, copper, indium, palladium, aluminum, iron, cobalt, nickel, an alloy thereof, an oxide thereof, or a mixture thereof.

4. The electromagnetic shielding composition of claim 2, wherein the nanoparticles are nanoparticles of silver, iron oxide, or a mixture thereof.

5. The electromagnetic shielding composition of claim 1, wherein the metal nanowires comprise from 1 to 11 percent by weight of the electromagnetic shielding composition.

6. The electromagnetic shielding composition of claim 1, wherein the metal nanowire has an aspect ratio of greater than 10.

7. The electromagnetic shielding composition of claim 1, wherein the sizes of the nanoparticles are less than 1000 nanometers.

8. The electromagnetic shielding composition of claim 1, wherein the content ratio of the metal nanowires to the nanoparticles is greater than 0.1.

9. The electromagnetic shielding composition of claim 1, wherein the metal nanowire comprises gold, silver, copper, indium, palladium, aluminum, iron, cobalt, nickel, an alloy thereof, an oxide thereof, or a mixture thereof.

10. The electromagnetic shielding composition of claim 1, wherein the material of the nanowire is gold-coated silver, silver-coated gold, gold-coated copper, copper-coated gold, silver-coated copper, copper-coated silver, or a combination thereof.

11. The electromagnetic shielding composition of claim 1, wherein the material of the nanoparticle is gold-coated silver, silver-coated gold, gold-coated copper, copper-coated gold, silver-coated copper, copper-coated silver, or a combination thereof.

12. An electromagnetic shielding composition, comprising:
a carrier;
a plurality of metal nanowires dispersed within the carrier and having aspect ratios greater than 10, wherein the metal nanowires comprise gold, silver, copper, indium, palladium, aluminum, iron, cobalt, nickel, an alloy thereof, an oxide thereof, or a mixture thereof, wherein the plurality of metal nanowires comprise from 1 to 95 percent based upon the total weight of the electromagnetic shielding composition taken as 100 percent by weight; and
a plurality of nanoparticles dispersed within the carrier, wherein the nanoparticles have a size of less than 1000 nanometers and comprise gold, silver, copper, indium, palladium, aluminum, iron, cobalt, nickel, an alloy thereof, an oxide thereof, or a mixture thereof, wherein the plurality of nanoparticles comprise from 0.1 to 60 percent based upon the total weight of the electromagnetic shielding composition taken as 100 percent by weight.

13. The electromagnetic shielding composition of claim 12, wherein the metal nanowires comprise from 1 to 11 percent by weight of the electromagnetic shielding composition and the nanoparticles comprise from 0.5 to 10 percent by weight of the electromagnetic shielding composition such that the shielding effectiveness of the composition is greater than 10 dB.

14. The electromagnetic shielding composition of claim 12, wherein the metal nanowires have aspect ratios of from 20 to 500, the nanoparticles have a size of from 10 to 1000 nanometers, and the metal nanowires comprise from 1 to 3 percent by weight of the electromagnetic shielding composition, and the metal nanowires comprise from 0.5 to 2 percent by weight such that the shielding effectiveness of the composition is greater than 10 dB.

15. An electromagnetic shielding device, comprising:
a body member including a surface; and
a thin film formed on the surface of the body member for shielding electromagnetic radiation, the thin film comprising:
a plurality of metal nanowires dispersed within the thin film, wherein the plurality of metal nanowires comprise from 1 to 95 percent based upon the total weight of the thin film taken as 100 percent by weight; and
a plurality of nanoparticles dispersed within the thin film, wherein the plurality of nanoparticles comprise from 0.1 to 60 percent based upon the total weight of the thin film taken as 100 percent by weight.

16. The electromagnetic shielding device of claim 15, wherein the nanoparticles are electrically conductive particles, magnetic particles, insulated magnetic particles, or a mixture thereof, which comprise from 0.5 to 2 percent by weight of the thin film.

17. An anti-electrostatic device, comprising:
a substrate; and
a thin film formed on the substrate, comprising:
a plurality of metal nanowires dispersed within the thin film, wherein the metal nanowires comprise from 1 to 95 percent based upon the total weight of the thin film taken as 100 percent by weight; and
a plurality of nanoparticles dispersed within the thin film, wherein the nanoparticles comprise from 0.1 to 60 percent based upon the total weight of the thin film taken as 100 percent by weight.

18. The anti-electrostatic device of claim 17, wherein the nanoparticles are electrically conductive particles, magnetic particles, insulated magnetic particles, or a mixture thereof, which comprise from 0.5 to 2 percent by weight of the thin film.

19. A method of manufacturing an electromagnetic shielding structure, comprising the steps of:
providing a target;
providing a mixture comprising a plurality of metal nanowires having aspect ratios greater than 50;
forming a first thin film on a surface of the target using the mixture; and
heating the first thin film at a temperature in a range of from 50 to 250 degrees Celsius.

20. The method of claim 19, wherein the metal nanowire comprises gold, silver, copper, indium, palladium, aluminum, iron, cobalt, nickel, an alloy thereof, an oxide thereof, or a mixture thereof.

21. The method of claim 19, wherein the mixture comprises a plurality of nanoparticles, which are particles of silver, iron oxide, or a mixture thereof.

22. The method of claim 21, wherein the nanoparticles comprise from 0.1 to 5 percent by weight of the first thin film.

23. The method of claim 21, wherein the nanoparticles are smaller than 1000 nanometers.

24. The method of claim 19, further comprising a second thin film comprising a plurality of nanoparticles, wherein the first and second thin films are stacked on each other.

25. The method of claim 19, wherein the heating of the first thin film causes the thin film to have improved shielding effectiveness at frequencies of from 4 GHz and 16 GHz.
